(19) United States
(12) Patent Application Publication
(10) Pub. No.: US 2025/0329683 A1
(43) Pub. Date: Oct. 23, 2025

(54) SEMICONDUCTOR PACKAGE

(71) Applicant: Samsung Electronics Co., Ltd., Suwon-si (KR)

(72) Inventors: Hyeon Jae Kim, Suwon-si (KR); Yong Jae Kim, Suwon-si (KR); Sung Woo Park, Suwon-si (KR); Jun Seop Byeon, Suwon-si (KR); Se Min Oh, Suwon-si (KR)

(21) Appl. No.: 18/958,102

(22) Filed: Nov. 25, 2024

(30) Foreign Application Priority Data
Apr. 18, 2024 (KR) 10-2024-0052305

(51) Int. Cl. H01L 23/00; H01L 23/13; H01L 23/498; H01L 25/18; H10B 80/00

(52) U.S. Cl. CPC H01L 24/32; H01L 23/13; H01L 23/49833; H01L 23/49816; H01L 24/16; H01L 24/73; H01L 25/18; H01L 2224/16146; H01L 2224/16227; H01L 2224/32112; H01L 2224/32145; H01L 2224/32225; H01L 2224/73204; H10B 80/00

(57) ABSTRACT

A semiconductor package is provided. The semiconductor package includes a substrate including a first wiring structure, a first surface and a second surface, an interposer on the second surface, a scribe lane region, and a chip region defined by the scribe lane region, and a third surface and a fourth surface, a first semiconductor chip on the fourth surface, and a mold layer on the fourth surface, and on at least a part of a side surface of the first semiconductor chip. The third surface is closer to the substrate than the fourth surface, the third surface includes a first sub-surface corresponding to the scribe lane region and a second sub-surface corresponding to the chip region, and a distance in the first direction from the second surface to the second sub-surface is less than a distance in the first direction from the second surface to the first sub-surface.

### CROSS-REFERENCE TO RELATED APPLICATION

This application claims priority from Korean Patent Application No. 10-2024-0052305 filed on Apr. 18, 2024 in the Korean Intellectual Property Office, and all the benefits accruing therefrom under 35 U.S.C. 119, the contents of which in its entirety are incorporated herein by reference.

### BACKGROUND

The present disclosure relates to a semiconductor package, and more particularly, to a semiconductor package in which a phenomenon that cracks occur in a semiconductor chip during a sawing process of separating a wafer for each of semiconductor chips is suppressed.

When a mold process progresses during a chip on wafer (CoW) process, a degree of internal stress applied to a wafer that generally has a small thickness relatively increases due to a thermal expansion coefficient between a mold material and the wafer. When a sawing process progresses later, the wafer and the mold are cut by a blade and the internal stress applied to the wafer is released at once, so that cracks may occur in a region of a semiconductor chip that is susceptible to external impact.

### SUMMARY

Aspects of the present disclosure provide a semiconductor package in which a phenomenon that cracks occur in a semiconductor chip during a sawing process is suppressed.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments of the present disclosure, there is provided a semiconductor package including a substrate including a first wiring structure, and including a first surface and a second surface opposite to each other in a first direction, an interposer on the second surface of the substrate, including a scribe lane region, and a chip region defined by the scribe lane region, and including a third surface and a fourth surface opposite to each other in the first direction, a first semiconductor chip on the fourth surface of the interposer, and a mold layer on the fourth surface of the interposer, and on at least a part of a side surface of the first semiconductor chip, wherein the third surface of the interposer is closer to the substrate than the fourth surface of the interposer, the third surface includes a first sub-surface corresponding to the scribe lane region and a second sub-surface corresponding to the chip region, and a distance in the first direction from the second surface of the substrate to the second sub-surface is less than a distance in the first direction from the second surface of the substrate to the first sub-surface.

According to some embodiments of the present disclosure, there is provided a semiconductor package including a substrate including a wiring structure, and including a first surface and a second surface opposite to each other in a first direction, a first semiconductor chip on the second surface of the substrate, and including a third surface and a fourth surface opposite to each other in the first direction, the first semiconductor chip including a first region and a second region spaced apart from each other at both edge portions of the first semiconductor chip, and a third region between the first region and the second region, a second semiconductor chip on the fourth surface of the first semiconductor chip, and a mold layer on the fourth surface of the first semiconductor chip, on at least a part of a side surface of the second semiconductor chip, and including a fifth surface and a sixth surface opposite to each other in the first direction, wherein the third surface of the first semiconductor chip is closer to the substrate than the fourth surface of the first semiconductor chip, a distance in the first direction from the fourth surface of the first semiconductor chip to the fifth surface of the mold layer is less than a distance from the fourth surface of the first semiconductor chip to the sixth surface of the mold layer in the first direction, the third surface of the first semiconductor chip includes a first sub-surface corresponding to the first region and a second sub-surface corresponding to the third region, and a distance in the first direction from the sixth surface of the mold layer to the first sub-surface is less than a distance in the first direction from the sixth surface of the mold layer to the second sub-surface.

According to some embodiments of the present disclosure, there is provided a semiconductor package including a substrate including a wiring structure, and including a first surface and a second surface opposite to each other in a first direction, a buffer die on the second surface of the substrate, including a scribe lane region, and a chip region defined by the scribe lane region, and including a third surface and a fourth surface opposite to each other in the first direction, a plurality of core dies stacked on a first region among regions of the fourth surface, and a mold layer on a second region extending around the first region among the regions of the fourth surface in plan view and on at least a part of side surfaces of the plurality of core dies, wherein the third surface of the buffer die is closer to the substrate than the fourth surface, the buffer die includes a recess that is recessed inward from the third surface of the buffer die in the first direction, and the recess is formed in a region corresponding to the scribe lane region of the third surface of the buffer die.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram illustrating a semiconductor package according to some embodiments.

FIGS. 2, 3, and 4 are diagrams illustrating semiconductor packages according to some embodiments.

FIG. 5 is a diagram illustrating a semiconductor package according to some embodiments.

FIGS. 6 and 7 are diagrams illustrating semiconductor packages according to some embodiments.

FIGS. 8 and 9 are diagrams illustrating semiconductor packages according to some embodiments.

FIG. 10 is a flowchart illustrating a method for fabricating a semiconductor package according to some embodiments.

FIGS. 11, 12, 13, 14, 15, 16, 17, 18, 19, and 20 are views illustrating the intermediate steps of a method for fabricating a semiconductor package according to some embodiments.

FIGS. 21 and 22 are diagrams illustrating effects of a semiconductor package according to some embodiments.

### DETAILED DESCRIPTION OF THE EMBODIMENTS

Hereinafter, a semiconductor package and a method for fabricating a semiconductor package according to some embodiments will be described with reference to the accompanying drawings.

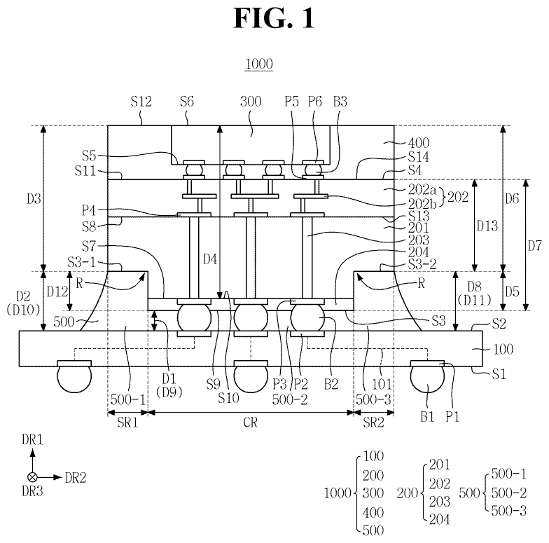

FIG. 1 is a diagram illustrating a semiconductor package according to some embodiments.

Referring to FIG. 1, a core die or semiconductor package 1000 may include a substrate 100, an interposer 200, a semiconductor chip 300, a mold layer 400, and an underfill film 500.

In the following description, an upper surface (or top) and a lower surface (or bottom) may be set with respect to a first direction DR1. For example, the first direction DR1 may be referred to as an upward direction, and the opposite direction of the first direction DR1 may be referred to as a downward direction.

The substrate 100 may have a plate shape including a surface S1 and a surface S2 that are opposite to each other in the first direction DR1. The substrate 100 may be a printed circuit board (PCB), but is not limited thereto.

When the substrate 100 is a PCB, the substrate 100 may be formed of at least one material selected from phenol resin, epoxy resin, or polyimide. The substrate 100 may include at least one material selected from the group including tetrafunctional epoxy, polyphenylene ether, epoxy/polyphenylene oxide, bismaleimide triazine (BT), Thermount, cyanate ester, and/or a liquid crystal polymer. The substrate 100 may contain a resin, e.g., prepreg, Ajinomoto build-up film (ABF), FR-4, or bismaleimide triazine (BT), impregnated into a core material such as glass fiber, glass cloth, or glass fabric, together with an inorganic filler.

A pad P1 may be disposed on the surface S1 of the substrate 100, and a pad P2 may be disposed on the surface S2 of the substrate 100. The pad P1 may be patterned in a solder resist layer disposed on the surface S1 of the substrate 100, and the pad P2 may be patterned in a solder resist layer disposed on the surface S2 of the substrate 100. Each of the pads P1 and P2 may include at least one of copper (Cu), aluminum (Al), silver (Ag), tin (Sn), gold (Au), nickel (Ni), lead (Pb), titanium (Ti), or an alloy thereof, but is not limited thereto.

A wiring structure 101 that electrically connects the pad P1 to the pad P2 may be included in the substrate 100. The wiring structure 101 may include a plurality of wiring vias that electrically connect a connection terminal B1 to components on the surface S2 of the substrate 100. The wiring structure 101 may include at least one of copper (Cu), aluminum (Al), silver (Ag), tin (Sn), gold (Au), nickel (Ni), lead (Pb), titanium (Ti), or an alloy thereof, but is not limited thereto. The connection terminal B1 may be disposed on the surface S1 of the substrate 100. The connection terminal B1 may be attached to the pad P1 exposed by the solder resist layer disposed on the surface S1 of the substrate 100. The connection terminal B1 may electrically connect the wiring structure 101 to an external device (e.g., a module substrate, a system board, or the like) of the semiconductor package 1000. Accordingly, the connection terminal B1 may provide an electrical signal to the wiring structure 101, or may provide an electrical signal provided from the wiring structure 101 to an external device of the semiconductor package 1000.

The connection terminal B1 may be a solder bump, but is not limited thereto. The connection terminal B1 may have various shapes such as a land, a ball, a pin, a pillar, and the like. The number, interval, and arrangement pattern of the connection terminals B1 are not limited to those shown in the drawing, and may vary depending on designs. The connection terminal B1 may include at least one of, for example, tin (Sn), indium (In), lead (Pb), zinc (Zn), nickel (Ni), gold (Au), silver (Ag), copper (Cu), antimony (Sb), bismuth (Bi), or a combination thereof, but is not limited thereto.

A bump B2 may be disposed on the pad P2. The bump B2 may electrically connect the substrate 100 to the interposer 200 disposed on the substrate 100. The bump B2 may include at least one of gold (Au), silver (Ag), copper (Cu), or aluminum (Al).

The interposer 200 may be disposed on the surface S2 of the substrate 100. The interposer 200 may include a surface S3 and a surface S4 that are opposite to each other in the first direction DR1. The interposer 200, which is a silicon interposer substrate (Si interposer substrate), may be a support substrate on which the semiconductor chip 300 is mounted. The interposer 200 may include a base substrate 201, a circuit layer 202, a through via 203, and a passivation layer 204.

The base substrate 201 may be disposed on the substrate 100, and may include a surface S7 facing the substrate 100 and a surface S8 opposite to the surface S7 in the first direction DR1. The base substrate 201 may be a semiconductor wafer. The base substrate 201 may have a rectangular shape in which a side in a second direction DR2 is greater than a side in a third direction DR3. The base substrate 201 may include a semiconductor element such as silicon and germanium, or a compound semiconductor such as silicon carbide (SiC), gallium arsenide (GaAs), indium arsenide (InAs), and/or indium phosphide (InP). The surface S7 or S8 of the base substrate 201 may be covered with or overlapped by an insulating film formed of a silicon oxide film, a silicon nitride film, or a combination thereof.

The circuit layer 202 may be disposed on the surface S8 of the base substrate 201. The circuit layer 202 may be in contact with the surface S8 of the base substrate 201. However, the location of the circuit layer 202 is not limited thereto, and the circuit layer 202 may be disposed on the surface S7 of the base substrate 201 depending on embodiments. The circuit layer 202 may include a surface S13 and a surface S14 that are opposite to each other in the first direction DR1. The surface S13 corresponding to the lower surface of the circuit layer 202 may be on the same plane as the surface S8 of the base substrate 201. The surface S14 corresponding to the upper surface of the circuit layer 202 may be on the same plane as a surface S11 corresponding to the lower surface of the mold layer 400. The circuit layer 202 may include an insulating member 202a and a wiring structure 202b.

The insulating member 202a may be an insulating layer covering or overlapping the wiring structure 202b. The insulating member 202a may include silicon oxide or silicon nitride.

The wiring structure 202b may be disposed in the insulating member 202a. The wiring structure 202b may include a plurality of wiring patterns spaced apart in the first direction DR1 and a plurality of vias connecting the plurality of wiring patterns.

Each of the plurality of wiring patterns may be a power wiring, a ground wiring, a signal wiring, or the like. The number of layers of the plurality of wiring patterns is not limited to the number shown in the drawing, and three to five pattern layers may be stacked, for example. The thickness of the plurality of wiring patterns may be within a range of about 1 μm to about 2 μm. The plurality of vias may electrically connect the plurality of wiring patterns to each other or electrically connect the plurality of wiring patterns to pads P4 and P5.

The wiring structure 202b may electrically and/or physically connect the through via 203 to the semiconductor chip 300. The wiring structure 202b may be electrically connected to the wiring structure 101 of the substrate 10 through the through via 203. Accordingly, the wiring structure 202b may electrically connect the semiconductor chip 300 to the wiring structure 101 of the substrate 10. The wiring structure 202b may include, a metal material, for example, an alloy containing two or more metals or at least one metal selected from the group including copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). However, the material of the wiring structure 202b is not limited to the above-mentioned materials.

The through via 203 may be a through silicon via (TSV) that penetrates or extends into the base substrate 201 in the first direction DR1. The through via 203 may provide an electrical path that connects a pad P3 formed on the surface S7 of the base substrate 201 to the pad P4 formed on the surface S8 of the base substrate 201. The through via 203 may electrically connect the wiring structure 101 of the substrate 100 to the wiring structure 202b of the interposer 200.

The through via 203 may include a metal material, such as tungsten (W), titanium (Ti), aluminum (Al), or copper (Cu), and include a metal compound such as tungsten nitride (WN), titanium nitride (TiN), or tantalum nitride (TaN). The through via 203 may be formed by a plating process, a PVD process, or a CVD process.

The passivation layer 204 may be formed on the surface S7 of the base substrate 201. The passivation layer 204 may include a surface S9 and a surface S10 that are opposite to each other in the first direction DR1. The surface S9 may be disposed close to the substrate 100. The surface S9 corresponding to the lower surface of the passivation layer 204 may be on the same plane as the surface S3 corresponding to the lower surface of the interposer 200. The surface S10 corresponding to the upper surface of the passivation layer 204 may be on the same plane as the surface S7 corresponding to the lower surface of the base substrate 201.

The passivation layer 204 may be a layer that covers or overlaps a part of the through via 203 exposed by removing a part of the base substrate 201 by a CMP process or the like. The passivation layer 204 may be formed of an insulating layer such as a silicon oxide film, a silicon nitride film, a silicon oxynitride film, or the like. However, the material of the passivation layer 204 is not limited to the above materials. For example, the passivation layer 204 may be formed of a polymer such as polyimide (PI). Further, the passivation layer 204 is not formed only on the surface S7 of the base substrate 201, but may also be formed on the upper surface of the circuit layer 202. Inside the passivation layer 204, the pad P3 may be patterned in a region in contact with the lower surface of the through via 203.

The pad P3 may be disposed on the surface S7 of the base substrate 201. The pad P3 may be in contact with the passivation layer 204 disposed on the surface S7 of the base substrate 201. The pad P3 may be in physical contact with the bump B2. The pad P3 may include, a metal material, for example, an alloy containing two or more metals or at least one metal selected from the group including copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The pad P4 may be disposed on the surface S8 of the base substrate 201. The pad P4 may be disposed in a region in contact with the surface S14 corresponding to the upper surface of the circuit layer 202. The pad P4 may be in physical contact with the through via 203. The pad P4 may include, a metal material, for example, an alloy including two or more metals or at least one metal selected from the group including copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The semiconductor chip 300 may be disposed on the interposer 200. The semiconductor chip 300 may include a surface S5 and a surface S6 that are opposite to each other in the first direction DR1. The surface S5 corresponding to the lower surface of the semiconductor chip 300 may be disposed close to the interposer 200. The semiconductor chip 300 may include a plurality of pads P6. The plurality of pads P6 may include a signal pad for connecting the semiconductor chip 300 to the interposer 200, and a ground pad and a power pad to be connected to the outside through a wiring. A bump B3 may be disposed between the semiconductor chip 300 and the interposer 200. The upper surface of the bump B3 may be in contact with the pad P6, and the lower surface of the bump B3 may be in contact with the pad P5.

The semiconductor chip 300 may include, for example, a logic chip such as an application-specific IC (ASIC), a central processing unit (CPU), a graphics processing unit (GPU), a field programmable gate array (FPGA), a digital signal processor (DSP), a cryptographic processor, a microprocessor, a microcontroller, or an analog-to-digital converter.

In some embodiments, the semiconductor chip 300 may include a volatile memory device such as a dynamic RAM (DRAM) or static RAM (SRAM), a non-volatile memory device such as a phase-change RAM (PRAM), magnetic RAM (MRAM), resistive RAM (RRAM) or flash memory device, or the like.

In addition to the semiconductor chip 300, at least one semiconductor chip may be further mounted on the interposer 200. Some of the plurality of pads P6 included in the semiconductor chip 300 may be pads for connecting another semiconductor chip mounted on the interposer 200 to the semiconductor chip 300.

The mold layer 400 may be disposed on the surface S4 of the interposer 200. The mold layer 400 may include the surface S11 and a surface S12 that are opposite to each other in the first direction DR1. The surface S11 may be in contact with the surface S4 of the interposer 200. The surface S11 corresponding to the lower surface of the mold layer 400 may be located on the same plane as the surface S4 corresponding to the upper surface of the interposer 200. Although FIG. 1 illustrates that the surface S12 of the mold layer 400 is located on the same plane as the surface S6 of the semiconductor chip 300, and the surface S6 of the semiconductor chip 300 is exposed by the mold layer 400, the embodiment is not limited thereto. For example, in some embodiments, the surface S12 corresponding to the upper surface of the mold layer 400 may be located at a higher level in the first direction DR1 than the surface S6 of the semiconductor chip 300, so that the mold layer 400 may cover, overlap, or be on the surface S6 of the semiconductor chip 300.

The mold layer 400 may cover, overlap, or be on at least a part of the side surface of the semiconductor chip 300, and may cover, overlap, or be on the surface S4 of the interposer 200. The mold layer 400 may cover, overlap, or be on at least a part of the surface S5 corresponding to the lower surface of the semiconductor chip 300, and may cover, overlap, or be on the pad P5 and the bump B3. The mold layer 400 may include an insulating resin, e.g., prepreg, Ajinomoto build-up film (ABF), FR-4, bismaleimide triazine (BT), epoxy molding compound (EMC), or the like.

The interposer 200 may include scribe lane regions SR1 and SR2 and a chip region CR. The scribe lane regions SR1 and SR2 may define the chip region CR. That is, the chip region CR may be surrounded by the scribe lane regions SR1 and SR2. The semiconductor chip 300 mounted on the interposer 200 may overlap the chip region CR in the first direction DR1. Further, the semiconductor chip 300 may not overlap the scribe lane regions SR1 and SR2 in the first direction DR1. When another semiconductor chip other than the semiconductor chip 300 is mounted on the interposer 200, the another semiconductor chip may also overlap the chip region CR in the first direction DR1.

The lower surface of the interposer 200 may be divided into three surfaces S3, S3-1, and S3-2. The sub-surface S3-1 and the sub-surface S3-2 may be disposed at both edge portions of the interposer 200, and the sub-surface S3-1 and the sub-surface S3-2 may be spaced apart from each other in the second direction DR2. The sub-surface S3-1 may correspond to the scribe lane region SR1, and the sub-surface S3-2 may correspond to the scribe lane region SR2. The surface S3 may be disposed between the sub-surface S3-1 and the sub-surface S3-2. The surface S3 may correspond to the chip region CR. The surface S3 may be on the same plane as the surface S9 corresponding to the lower surface of the passivation layer 204.

The lower surface of the interposer 200 may have a stepped portion in the first direction DR1 depending on whether it corresponds to the chip region CR or the scribe lane regions SR1 and SR2. For example, the surface S3 disposed at the center of the lower surface of the interposer 200 may include a shape that protrudes more in the opposite direction of the first direction DR1 than the sub-surfaces S3-1 and S3-2 respectively disposed at both edge portions of the lower surface of the interposer 200.

The lower surface of the interposer 200 may include recesses R. One recess R may be formed in each of the sub-surfaces S3-1 and S3-2 respectively disposed at both edge portions of the lower surface of the interposer 200. Each of the recesses R may have a shape that is recessed inward from the surface S3 disposed at the center of the lower surface of the interposer 200. For example, the recesses R may be portions recessed in the first direction DR1 from the surface S3 of the interposer 200 corresponding to the chip region CR. The recesses R may be disposed at both edge portions of the interposer 200. Any one recess R may correspond to the scribe lane region SR1, and another recess R may correspond to the scribe lane region SR2.

The recess R corresponding to the scribe lane region SR1 may be formed to be recessed by a length D12 in the first direction DR1 from the surface S3 of the interposer 200. That is, the length in the first direction DR1 from the surface S3 of the lower surface of the interposer 200 to the sub-surface S3-1 of the lower surface of the interposer 200 may be the length D12.

The recess R corresponding to the scribe lane region SR2 may be formed to be recessed by a length D5 in the first direction DR1 from the surface S3 of the interposer 200. That is, the length in the first direction DR1 from the surface S3 of the lower surface of the interposer 200 to the sub-surface S3-2 of the lower surface of the interposer 200 may be the length D5. In this case, the length D12 and the length D5 may be the same or different depending on embodiments.

In this way, since the recesses R are formed at both edge portions of the lower surface of the interposer 200, the length from the substrate 100 to the lower surface of the interposer 200 may vary depending on whether it is the scribe lane regions SR1 and SR2 or the chip region CR.

For example, a length D1 in the first direction DR1 from the surface S2 of the substrate 100 to the surface S3 of the lower surface of the interposer 200 may be less than a length D2 in the first direction DR1 from the surface S2 of the substrate 100 to the sub-surface S3-1 of the lower surface of the interposer 200.

Further, the length D1 in the first direction DR1 from the surface S2 of the substrate 100 to the surface S3 of the lower surface of the interposer 200 may be less than a length D8 in the first direction DR1 from the surface S2 of the substrate 100 to the sub-surface S3-2 of the lower surface of the interposer 200.

In this case, the length D2 in the first direction DR1 from the surface S2 of the substrate 100 to the sub-surface S3-1 of the lower surface of the interposer 200 may be the same as the length D8 in the first direction DR1 from the surface S2 of the substrate 100 to the sub-surface S3-2 of the lower surface of the interposer 200. However, the length D2 and the length D8 may be different from each other depending on embodiments.

Further, a length D3 in the first direction DR1 from the surface S12 corresponding to the upper surface of the mold layer 400 to the sub-surface S3-1 of the lower surface of the interposer 200 may be less than a length D4 from the surface S12 of the mold layer 400 to the surface S3 of the lower surface of the interposer 200.

Further, a length D6 in the first direction DR1 from the surface S12 corresponding to the upper surface of the mold layer 400 to the sub-surface S3-2 of the lower surface of the interposer 200 may be less than the length D4 from the surface S12 of the mold layer 400 to the surface S3 of the lower surface of the interposer 200.

A length D7 in the first direction DR1 of the interposer 200 may be the same as the length measured in the first direction DR1 from the surface S3 to the surface S4 of the interposer 200. In some embodiments, with respect to the length in the first direction DR1 of the interposer 200, a degree in which the recesses R are recessed from the surface S3 of the lower surface of the interposer 200 may have a specific length ratio. For example, the recess R formed in the sub-surface S3-2 may be formed to be recessed by at least ½ of the length D7 in the first direction DR1 of the interposer 200. Accordingly, a length D13 in the first direction DR1 from the surface S14 of the circuit layer 202 corresponding to the same plane as the surface S4 of the interposer 200 to the sub-surface S3-2 may be less than or equal to ½ of the length D7 in the first direction DR1 from the surface S14 of the circuit layer 202 to the surface S9 of the passivation layer 204.

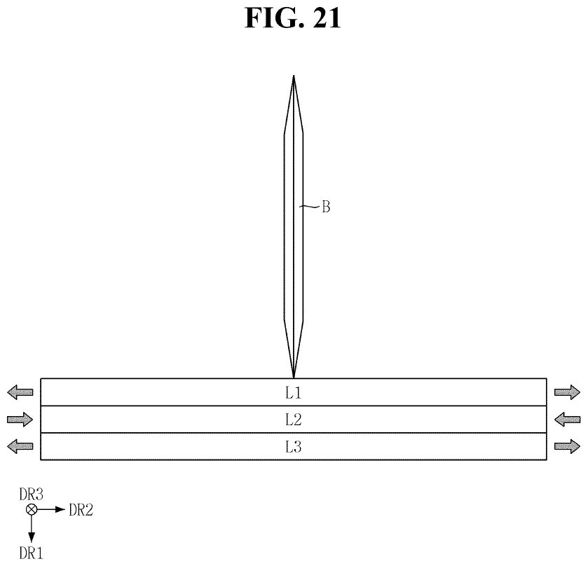

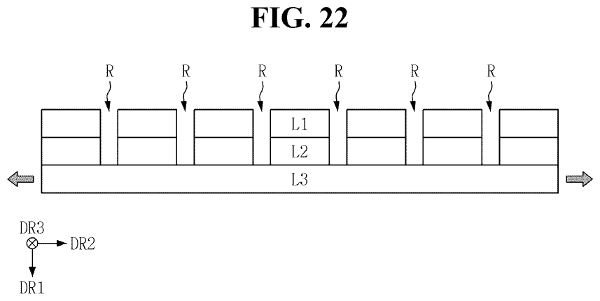

When the length D13 is greater than ½ of the length D7, the effect according to some embodiments of the present disclosure, which will be described later with reference to FIGS. 21 and 22, that is, the stepped portion of the scribe lane region SR2 required for suppressing a phenomenon that the internal stress of the passivation layer 204, the base substrate 201, the circuit layer 202, and the mold layer 400 that are cut by a blade during a sawing process is released at once and cracks occur in the semiconductor chip 300 may not be sufficiently secured.

The above description may be equally applied to the recess R formed in the sub-surface S3-1.

In this way, in some embodiments, the recesses R may be recessed inward from the sub-surface S3 that protrudes most in the opposite direction of the first direction DR1 in the lower surface of the interposer 200, thereby exposing at least a partial surface of the base substrate 201. Accordingly, the circuit layer 202 and the mold layer 400 may not be exposed.

The underfill film 500 may be interposed between the substrate 100 and the interposer 200 to fill the space between the substrate 100 and the interposer 200. The underfill film 500 may cover, overlap, or be on the bump B2. The underfill film 500 may include an insulating polymer material, e.g., epoxy resin.

Since the recesses R are formed at both edge portions of the lower surface of the interposer 200, the length in the first direction DR1 of the underfill film 500 may be different in the chip region CR and the scribe lane regions SR1 and SR2. For example, a length D9 in the first direction DR1 of the underfill film 500 disposed on the chip region CR may be less than a length D10 in the first direction DR1 of the underfill film 500 disposed on the scribe lane region SR1. In this case, the length D9 in the first direction DR1 of the underfill film 500 disposed on the chip region CR may be the same as the length D1 in the first direction DR1 from the surface S2 of the substrate 100 to the sub-surface S3 of the lower surface of the interposer 200, but embodiments are not limited thereto.

The underfill film 500 may include a sub-film 500-1 that partially or completely fills the space between the surface S2 and the sub-surface S3-1, a sub-film 500-2 that partially or completely fills the space between the surface S2 and the sub-surface S3, and a sub-film 500-3 that fills the space between the surface S2 and the sub-surface S3-2. In this case, the length in the first direction DR1 of the sub-film 500-2 may be the same as the length D9 in the first direction DR1 of the underfill film 500 disposed on the chip region CR. Further, the length in the first direction DR1 of the sub-film 500-1 may be the same as the length D10 in the first direction DR1 of the underfill film 500 disposed on the scribe lane region SR1. Further, the length in the first direction DR1 of the sub-film 500-3 may be the same as the length D11 in the first direction DR1 of the underfill film 500 disposed on the scribe lane region SR2.

Further, the length D9 in the first direction DR1 of the underfill film 500 disposed on the chip region CR may be less than the length D11 in the first direction DR1 of the underfill film 500 disposed on the scribe lane region SR2. In this case, the length D9 in the first direction DR1 of the underfill film 500 disposed on the chip region CR may be the same as the length D1 in the first direction DR1 from the surface S2 of the substrate 100 to the sub-surface S3 of the lower surface of the interposer 200, but the embodiments are not limited thereto.

Further, the length D10 in the first direction DR1 of the underfill film 500 disposed on the scribe lane region SR1 may be the same as the length D2 in the first direction DR1 from the surface S2 of the substrate 100 to the sub-surface S3-1 of the lower surface of the interposer 200, but the embodiments are not limited thereto.

Further, the length D11 in the first direction DR1 of the underfill film 500 disposed on the scribe lane region SR2 may be the same as the length D8 in the first direction DR1 from the surface S2 of the substrate 100 to the sub-surface S3-2 of the lower surface of the interposer 200, but the embodiments are not limited thereto.

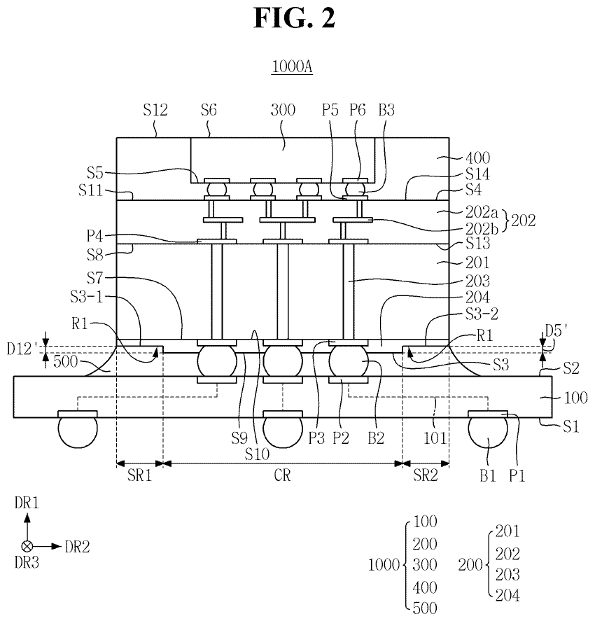

FIGS. 2, 3, and 4 are diagrams illustrating semiconductor packages according to some embodiments. Hereinafter, redundant description of the parts already described in the previous embodiments will be omitted and the differences will be mainly described.

Referring to FIG. 2, the lower surface of the interposer 200 included in a semiconductor package 1000A may include recesses R1 recessed inward from the sub-surface S3 that protrudes most in the opposite direction of the first direction DR1 in the lower surface of the interposer 200. For example, the recesses R1 may be portions recessed in the first direction DR1 from the sub-surface S3 of the lower surface of the interposer 200. The recesses R1 may be disposed at both edge portions of the interposer 200. Any one recess R1 may correspond to the scribe lane region SR1, and another recess R1 may correspond to the scribe lane region SR2.

Unlike the embodiment shown in FIG. 1, the recesses R1 may be recessed inward from the sub-surface S3 of the lower surface of the interposer 200, thereby exposing at least a partial surface of the passivation layer 204. Accordingly, the base substrate 201, the circuit layer 202, and the mold layer 400 may not be exposed.

The recess R1 corresponding to the scribe lane region SR1 may be formed to be recessed by a length D12′ in the first direction DR1 from the sub-surface S3 of the interposer 200. That is, the length in the first direction DR1 from the sub-surface S3 of the lower surface of the interposer 200 to the sub-surface S3-1 of the lower surface of the interposer 200 may be the length D12′. In this case, the length D12′ may be less than the length D12 of FIG. 1.

The recess R1 corresponding to the scribe lane region SR2 may be formed to be recessed by a length D5′ in the first direction DR1 from the sub-surface S3 of the interposer 200. That is, the length in the first direction DR1 from the sub-surface S3 of the lower surface of the interposer 200 to the sub-surface S3-2 of the lower surface of the interposer 200 may be the length D5′. In this case, the length D5′ may be less than the length D5 of FIG. 1. Further, the length D12′ and the length D5′ may be the same or different depending on embodiments.

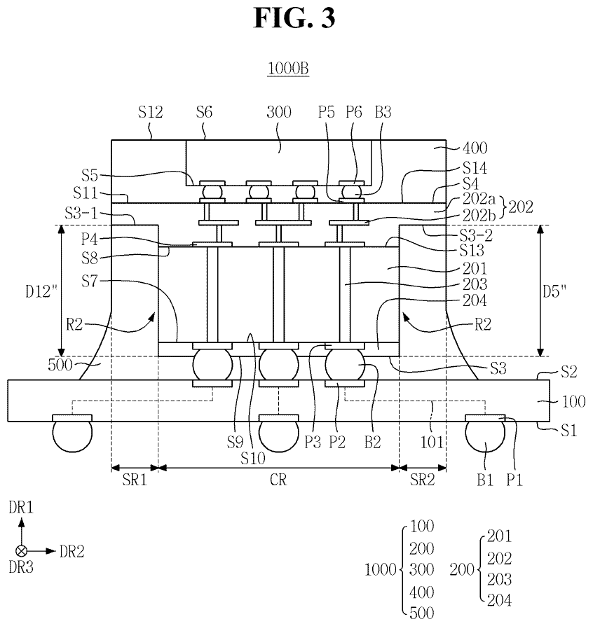

Referring to FIG. 3, the lower surface of the interposer 200 included in a semiconductor package 1000B may include recesses R2 recessed inward from the sub-surface S3 that protrudes most in the opposite direction of the first direction DR1 in the lower surface of the interposer 200. For example, the recesses R2 may be portions recessed in the first direction DR1 from the sub-surface S3 of the lower surface of the interposer 200. The recesses R2 may be disposed at both edge portions of the interposer 200. Any one recess R2 may correspond to the scribe lane region SR1, and another recess R2 may correspond to the scribe lane region SR2.

Unlike in the embodiments shown in FIGS. 1 and 2, the recesses R2 may be recessed inward from the sub-surface S3 of the lower surface of the interposer 200, thereby exposing at least a partial surface of the circuit layer 202. Accordingly, the mold layer 400 may not be exposed.

The recess R2 corresponding to the scribe lane region SR1 may be formed to be recessed by a length D12″ in the first direction DR1 from the sub-surface S3 of the interposer 200. That is, the length in the first direction DR1 from the sub-surface S3 of the lower surface of the interposer 200 to the sub-surface S3-1 of the lower surface of the interposer 200 may be the length D12″. In this case, the length D12″ may be greater than the length D12 of FIG. 1.

The recess R2 corresponding to the scribe lane region SR2 may be formed to be recessed by a length D5″ in the first direction DR1 from the sub-surface S3 of the interposer 200. That is, the length in the first direction DR1 from the sub-surface S3 of the lower surface of the interposer 200 to the sub-surface S3-2 of the lower surface of the interposer 200 may be the length D5″. In this case, the length D5″ may be greater than the length D5 of FIG. 1. Further, the length D12″ and the length D5″ may be the same or different depending on embodiments.

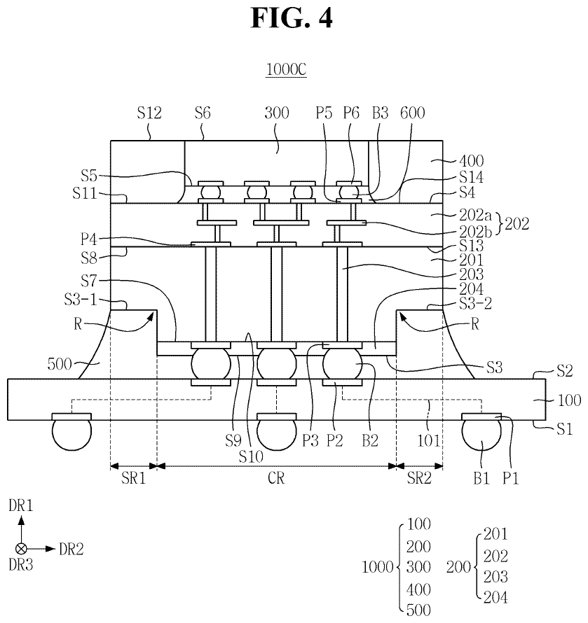

Referring to FIG. 4, a semiconductor package 1000C may further include an underfill film 600. The underfill film 600 may be interposed between the interposer 200 and the semiconductor chip 300 to partially or completely fill the space between the interposer 200 and the semiconductor chip 300. The underfill film 600 may cover, overlap, or be on the bump B3, and may cover, overlap, or be on at least a part of the surface S4 of the interposer 200. In this case, the mold layer 400 may cover, overlap, or be on a region of the surface S4 of the interposer 200 that is not covered or overlapped by the underfill film 600. The underfill film 600 may be different material from the mold layer 400.

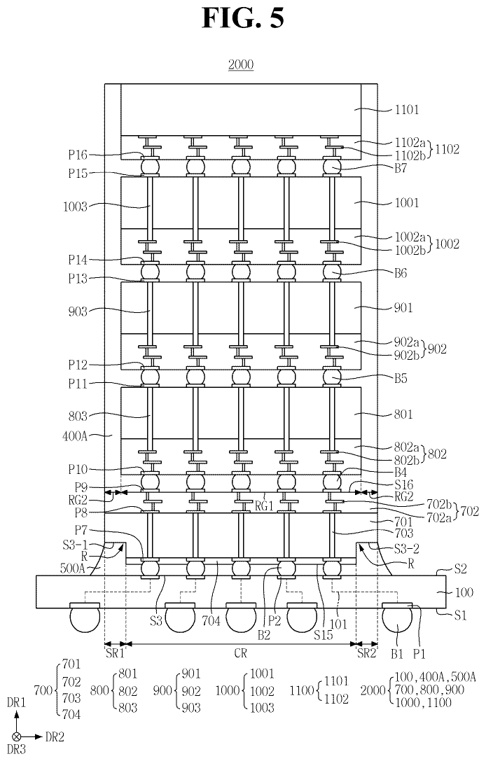

FIG. 5 is a diagram illustrating a semiconductor package according to some embodiments.

Referring to FIG. 5, a semiconductor package 2000 may include the substrate 100, a buffer die 700, a plurality of core dies 800, 900, 1000, and 1100, a mold layer 400A, and an underfill film 500A.

Since the substrate 100 is the same as the substrate 100 described with reference to FIG. 1, the description of the substrate 100 will be omitted below. The buffer die 700 and the plurality of core dies 800, 900, 1000, and 1100 may be disposed on the substrate 100.

The buffer die 700 and the plurality of core dies 800, 900, 1000, and 1100 may form a die structure. Although FIG. 5 illustrates that four core dies 800, 900, 1000, and 1100 are disposed on the buffer die 700, the embodiment is not limited thereto. Depending on embodiments, the semiconductor package 2000 may include eight, twelve, or sixteen core dies on the buffer die 700. However, it is assumed in the following description that the semiconductor package 2000 includes four core dies 800, 900, 1000, and 1100.

The core die 800 may be disposed on the buffer die 700, the core die 900 may be disposed on the core die 800, the core die 1000 may be disposed on the core die 900, and the core die 1100 may be disposed on the core die 1000. The buffer die 700 and the core dies 800, 900, 1000, and 1100 may be aligned in the first direction DR1.

In some embodiments, the buffer die 700 may not include a memory cell. For example, the buffer die 700 may include a test logic circuit such as a serial-parallel conversion circuit, a design for test (DFT), a joint test action group (JTAG), and a memory built-in self-test (MBIST), and a signal interface circuit such as PHY. For example, the buffer die 700 may be a buffer chip for controlling the core dies 800, 900, 1000, and 1100.

The core dies 800, 900, 1000, and 1100 may include a memory cell. For example, the core dies 800, 900, 1000, and 1100 may be a volatile memory such as a dynamic random access memory (DRAM) or a static random access memory (SRAM), or a non-volatile memory such as phase-change random access memory (PRAM), a magneto-resistive random access memory (MRAM), a ferroelectric random access memory (FeRAM), or a resistive random access memory (RRAM).

In some embodiments, the buffer die 700 and the core dies 800, 900, 1000, and 1100 may include a high bandwidth memory (HBM). For example, the buffer die 700 may be a buffer chip for controlling an HBM DRAM, and the core dies 800, 900, 1000, and 1100 may be a memory cell chip having a cell of the HBM DRAM controlled by the buffer die 700. The buffer die 700 may be referred to as a buffer chip, a master chip, or an HBM controller die, and each of the core dies 800, 900, 1000, and 1100 may be referred to as a memory chip, a slave chip, a DRAM dice, or a DRAM slice. The buffer die 700 and the core dies 800, 900, 1000, and 1100 stacked on the buffer die 700 may be collectively referred to as an HBM DRAM device, or an HBM DRAM chip.

In some embodiments, the buffer die 700 may include a physical layer and a direct access area. The physical layer of the buffer die 700 may include interface circuits for communication with an external host device, and the external host device may be electrically connected to the buffer die 700 through the connection terminal B1.

The core dies 800, 900, 1000, and 1100 may receive signals from the buffer die 700, or may transmit signals to the buffer die 700 through a physical layer. The signals received through the physical layer of the buffer die 700 may be transmitted to the core dies 800, 900, 1000, and 1100. The direct access area may provide an access path for testing the core dies 800, 900, 1000, and 1100 without passing through the buffer die 700. For example, the electrical properties of the core dies 800, 900, 1000, and 1100 may be tested through the access path provided by the direct access area. The direct access area may include a conductive device capable of performing direct communication with an external test device.

The buffer die 700 may be disposed on the surface S2 of the substrate 100. The buffer die 700 may include a surface S15 and a surface S16 that are opposite to each other in the first direction DR1. The surface S16 corresponding to the upper surface of the buffer die 700 may be divided into a region RG1 and a region RG2. The region RG2 may surround the region RG1. For example, the region RG1 may correspond to the central region of the surface S16 of the buffer die 700, and the region RG2 may correspond to an edge region surrounding the region RG1. The plurality of core dies 800, 900, 1000, and 1100 may be disposed on the region RG1 of the surface S16 of the buffer die 700.

The buffer die 700 may include a base substrate 701, a circuit layer 702, a through via 703, and a passivation layer 704.

The base substrate 701 may be disposed on the substrate 100, and may include a lower surface facing the substrate 100 and an upper surface opposite to the lower surface in the first direction DR1. The base substrate 701 may be a semiconductor wafer. The base substrate 701 may have a rectangular shape in which a side in a second direction DR2 is greater in length than a side in a third direction DR3. The base substrate 701 may include a semiconductor element such as silicon and germanium, or a compound semiconductor such as silicon carbide (SiC), gallium arsenide (GaAs), indium arsenide (InAs), and indium phosphide (InP). The bottom or upper surface of the base substrate 701 may be covered with or overlapped by an insulating film formed of a silicon oxide film, a silicon nitride film, or a combination thereof.

The circuit layer 702 may be disposed on the upper surface of the base substrate 701. The circuit layer 702 may be in contact with the upper surface of the base substrate 701. However, the location of the circuit layer 702 is not limited thereto, and the circuit layer 702 may be disposed on the lower surface of the base substrate 701, depending on embodiments. The circuit layer 702 may include a lower surface and an upper surface that are opposite to each other in the first direction DR1. The lower surface of the circuit layer 702 may be on the same plane as the upper surface of the base substrate 201. The upper surface of the circuit layer 702 may be on the same plane as the lower surface of the mold layer 400. The circuit layer 702 may include an insulating member 702a and a wiring structure 702b.

The insulating member 702a may be an insulating layer covering or overlapping the wiring structure 702b. The insulating member 702a may include silicon oxide or silicon nitride.

The wiring structure 702b may be disposed in the insulating member 702a. The wiring structure 702b may include a plurality of wiring patterns spaced apart in the first direction DR1 and a plurality of vias connecting the plurality of wiring patterns.

Each of the plurality of wiring patterns may be a power wiring, a ground wiring, a signal wiring, or the like. The number of layers of the plurality of wiring patterns is not limited to the number shown in the drawing, and three to five pattern layers may be stacked, for example. The thickness of the plurality of wiring patterns may be within a range of about 1 μm to about 2 μm. The plurality of vias may connect the plurality of wiring patterns to each other or connect the plurality of wiring patterns to pads P8 and P9.

The wiring structure 702b may electrically and/or physically connect the through via 703 to the core die 800. The wiring structure 702b may be electrically connected to the wiring structure 101 of the substrate 100 through the through via 703. Accordingly, the wiring structure 702b may electrically connect the core die 800 to the wiring structure 101 of the substrate 100. The wiring structure 702b may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). However, the material of the wiring structure 702b is not limited to the above-mentioned materials.

The through via 703 may be a through silicon via (TSV) that penetrates or extends into the base substrate 701 in the first direction DR1. The through via 703 may provide an electrical path that connects a pad P7 formed on the lower surface of the base substrate 701 to the pad P8 formed on the upper surface of the base substrate 701. The through via 703 may electrically connect the wiring structure 101 of the substrate 100 to the wiring structure 702b of the buffer die 700.

The through via 703 may include a metal material, such as tungsten (W), titanium (Ti), aluminum (Al), or copper (Cu), and include a metal compound such as tungsten nitride (WN), titanium nitride (TiN), or tantalum nitride (TaN). The through via 703 may be formed by a plating process, a PVD process, or a CVD process.

The passivation layer 704 may be formed on the lower surface of the base substrate 701. The passivation layer 704 may include a lower surface and an upper surface that are opposite to each other in the first direction DR1. The lower surface of the passivation layer 704 may be disposed close to the substrate 100. The lower surface of the passivation layer 704 may be on the same plane as the lower surface of the buffer die 700. The upper surface of the passivation layer 704 may be on the same plane as the lower surface of the base substrate 701.

The passivation layer 704 may be a layer that covers, overlaps, or is on a part of the through via 703 exposed by removing a part of the base substrate 701 by a CMP process or the like. The passivation layer 704 may be formed of an insulating layer such as a silicon oxide film, a silicon nitride film, a silicon oxynitride film, or the like. However, the material of the passivation layer 704 is not limited to the above materials. For example, the passivation layer 704 may be formed of a polymer such as polyimide (PI). Further, the passivation layer 704 is not formed only on the lower surface of the base substrate 701, but may also be formed on the upper surface of the circuit layer 702.

Inside the passivation layer 704, the pad P7 may be patterned in a region in contact with the lower surface of the through via 703. The pad P7 may be disposed on the lower surface of the base substrate 701. The pad P7 may be in contact with the passivation layer 704 disposed on the lower surface of the base substrate 701. The pad P7 may be in physical contact with the bump B2 and the through via 703. The pad P7 may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The pad P9 may be disposed on the upper surface of the base substrate 701. The pad P9 may be disposed in a region in contact with the upper surface of the circuit layer 702. The pad P9 may be in physical contact with the bump B4. The pad P9 may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The core die 800 may be disposed on the buffer die 700. The core die 800 may include a lower surface and an upper surface that are opposite to each other in the first direction DR1. The core die 800 may include a base substrate 801, a circuit layer 802, and a through via 803.

The base substrate 801 may be disposed on the substrate 100, and may include a lower surface facing the buffer die 700 and an upper surface opposite to the lower surface in the first direction DR1. The base substrate 801 may be a semiconductor wafer. The base substrate 801 may have a rectangular shape in which a side in the second direction DR2 is greater in length than a side in the third direction DR3. The base substrate 801 may include a semiconductor element such as silicon and germanium, or a compound semiconductor such as silicon carbide (SiC), gallium arsenide (GaAs), indium arsenide (InAs), and/or indium phosphide (InP). The bottom or upper surface of the base substrate 801 may be covered with or overlapped by an insulating film formed of a silicon oxide film, a silicon nitride film, or a combination thereof.

The circuit layer 802 may be disposed on the lower surface of the base substrate 801. The circuit layer 802 may be in contact with the lower surface of the base substrate 801. However, the location of the circuit layer 802 is not limited thereto, and the circuit layer 802 may be disposed on the upper surface of the base substrate 801 depending on embodiments. The circuit layer 802 may include a lower surface and an upper surface that are opposite to each other in the first direction DR1. The upper surface of the circuit layer 802 may be on the same plane as the lower surface of the base substrate 801.

The circuit layer 802 may include an insulating member 802a and a wiring structure 802b.

The insulating member 802a may be an insulating layer covering or overlapping the wiring structure 802b. The insulating member 802a may include silicon oxide or silicon nitride.

The wiring structure 802b may be disposed in the insulating member 802a. The wiring structure 802b may include a plurality of wiring patterns spaced apart in the first direction DR1 and a plurality of vias connecting the plurality of wiring patterns.

Each of the plurality of wiring patterns may be a power wiring, a ground wiring, a signal wiring, or the like. The number of layers of the plurality of wiring patterns is not limited to the number shown in the drawing, and three to five pattern layers may be stacked, for example. The thickness of the plurality of wiring patterns may be within a range of about 1 μm to about 2 μm. The plurality of vias may connect the plurality of wiring patterns to each other or connect the plurality of wiring patterns to the pads P8 and P9.

The wiring structure 802b may electrically and/or physically connect the through via 803 to the buffer die 700. The through via 803 may be electrically connected to the wiring structure 702b of the buffer die 700 through the wiring structure 802b. Accordingly, the wiring structure 802b may electrically connect the core die 800 to the wiring structure 702b of the buffer die 700. The wiring structure 702b may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). However, the material of the wiring structure 702b is not limited to the above-mentioned materials.

The through via 803 may be a through silicon via (TSV) that penetrates or extends into the base substrate 801 in the first direction DR1. The through via 803 may provide an electrical path that connects a pad P10 formed on the lower surface of the base substrate 801 to a pad P11 formed on the upper surface of the base substrate 801. The through via 803 may electrically connect the wiring structure 802b of the core die 800 to the wiring structure 902b of the core die 900.

The through via 803 may include a metal material, such as tungsten (W), titanium (Ti), aluminum (Al), or copper (Cu), and include a metal compound such as tungsten nitride (WN), titanium nitride (TiN), or tantalum nitride (TaN). The through via 203 may be formed by a plating process, a PVD process, or a CVD process.

The core die 900 may include a lower surface and an upper surface that are opposite to each other in the first direction DR1, and may include a base substrate 901, a circuit layer 902, and a through via 903. The core die 1000 may include a lower surface and a upper surface that are opposite to each other in the first direction DR1, and may include a base substrate 1001, a circuit layer 1002, and a through via 1003. The core die 1100 may include a lower surface and an upper surface that are opposite to each other in the first direction DR1, and may include a base substrate 1101 and a circuit layer 1102.

The core die 800 and the core die 900 may be physically and electrically connected to each other by pads P11 and P12 and a bump B5. The core die 900 and the core die 1000 may be physically and electrically connected to each other by pads P13 and P14 and a bump B6. The core die 1000 and the core die 1100 may be physically and electrically connected to each other by pads P15 and P16 and a bump B7.

The description of the core dies 900, 1000, and 1100 is the same as the description of the core die 800, so that the description of the core die 800 will replace the description of the other core dies 900, 1000, and 1100.

Among the plurality of core dies 800, 900, 1000, and 1100, the core die 1100 disposed at the uppermost end may not include a through via penetrating or extending into the base substrate 1101 in the first direction DR1, unlike the other core dies 800, 9000, and 1000.

The mold layer 400A may be disposed on the upper surface of the buffer die 700. The mold layer 400A may include a lower surface and an upper surface that are opposite to each other in the first direction DR1. The lower surface of the mold layer 400A may be in contact with the upper surface of the buffer die 700. The mold layer 400A may cover, overlap, or be on the side surfaces of the core dies 800, 900, 1000, and 1100, and may cover, overlap, or be on bumps B4, B5, B6, and B7, and pads P9, P11, P13, and P15. Further, the mold layer 400A may cover, overlap, or be on the upper surface of the buffer die 700, the lower surface and the upper surface of the core die 800, the lower surface and the upper surface of the core die 900, the lower surface and the upper surface of the core die 1000, and the lower surface of the core die 1100.

Although FIG. 5 illustrates that the upper surface of the mold layer 400A is located on the same plane as the upper surface of the core die 1100, and the upper surface of the core die 1100 is exposed by the mold layer, the embodiments are not limited thereto. For example, in some embodiments, the upper surface of the mold layer 400A may be located at a higher level in the first direction DR1 than the upper surface of the core die 1100, so that the mold layer 400A may cover, overlap, or be on the upper surface of the core die 1100.

The mold layer 400A may include an insulating resin, e.g., prepreg, Ajinomoto build-up film (ABF), FR-4, bismaleimide triazine (BT), epoxy molding compound (EMC), or the like.

Similarly to the interposer 200 of FIG. 1, the buffer die 700 may include the scribe lane regions SR1 and SR2 and the chip region CR. The scribe lane regions SR1 and SR2 may define the chip region CR. That is, the chip region CR may be surrounded by the scribe lane regions SR1 and SR2. The core dies 800, 900, 1000, and 1100 mounted on the buffer die 700 may overlap the chip region CR in the first direction DR1. In addition, the core dies 800, 900, 1000, and 1100 may not overlap the scribe lane regions SR1 and SR2 in the first direction DR1.

The lower surface of the buffer die 700 may be divided into three surfaces S3, S3-1, and S3-2. Further, the lower surface of the buffer die 700 may include the recesses R recessed inward from the sub-surface S3 that protrudes most in the first direction DR1 in the lower surface of the buffer die 700. The description of the three surfaces S3, S3-1, and S3-2 of the lower surface of the buffer die 700 and the recesses R formed in the lower surface of the buffer die 700 is the same as the description of the three surfaces S3, S3-1, and S3-2 of the lower surface of the interposer 200 and the recesses R formed in the lower surface of the interposer 200 which was made with reference to FIG. 1, so that redundant description will be omitted below.

The recesses R formed to be recessed inward from the sub-surface S3 of the lower surface of the buffer die 700 may expose at least a partial surface of the base substrate 701 of the buffer die 700. Accordingly, the circuit layer 702 of the buffer die 700 and the mold layer 400A formed on the buffer die 700 may not be exposed by the recesses R.

However, depending on embodiments, as shown in FIG. 2, the recesses R may be less recessed into the buffer die 700 compared to that shown in FIG. 5, so that a part of the passivation layer 704 may be exposed, and the base substrate 701, the circuit layer 702, and the mold layer 400A may not be exposed.

In some embodiments, as shown in FIG. 3, the recesses R may be more recessed into the buffer die 700 compared to that shown in FIG. 5, so that the circuit layer 702 may be exposed. However, also in this case, the mold layer 400A may not be exposed.

The underfill film 500A may be interposed between the substrate 100 and the buffer die 700 to fill the space between the substrate 100 and the buffer die 700. The underfill film 500A may cover, overlap, or be on the bump B2, the lower surface of the passivation layer 704, and the upper surface of the substrate 100. Further, the underfill film 500A may fill the recesses R recessed inward from the sub-surface S3 of the buffer die 700. The underfill film 500A may include an insulating polymer material, e.g., epoxy resin. The description of the underfill film 500A is the same as the description of the underfill film 500 shown in FIG. 1, so that the redundant description will be omitted below.

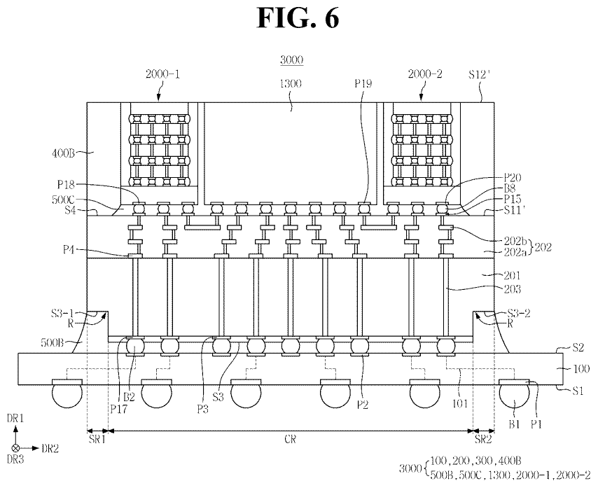

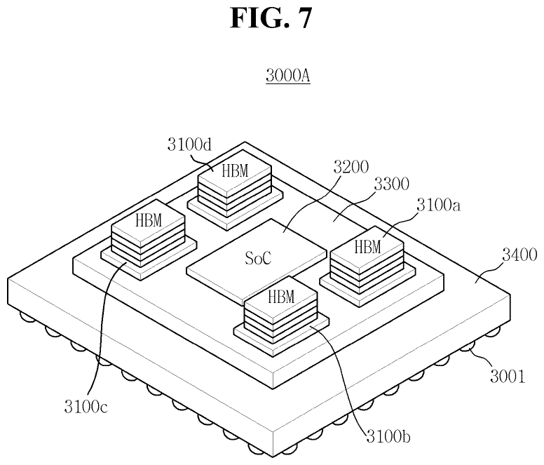

FIGS. 6 and 7 are diagrams illustrating semiconductor packages according to some embodiments.

Referring to FIG. 6, a semiconductor package 3000 may include the substrate 100, the interposer 200, a semiconductor chip 1300, a semiconductor chip 2000-1, a semiconductor chip 2000-2, a mold layer 400B, an underfill film 500B, and an underfill film 500C. Since the interposer 200 of FIG. 6 is the same as the interposer 200 of FIG. 1, the description of the parts already described in the previous embodiments will be omitted and the differences will be mainly described.

The semiconductor chips 1300, 2000-1, and 2000-2 may be disposed horizontally on the interposer 200. The semiconductor chips 1300, 2000-1, and 2000-2 may be disposed on the interposer 200 to be spaced apart from each other in the second direction DR2. The semiconductor chip 1300 may include a pad P19, and may be connected to the interposer 200 through a bump B8 attached to the pad P19 and a pad P15 attached to the bump B8.

The semiconductor chip 2000-1 may include a pad P18, and may be connected to the interposer 200 through the bump B8 attached to the pad P18 and the pad P15 attached to the bump B8. The semiconductor chip 2000-2 may include a pad P20, and may be connected to the interposer 200 through the bump B8 attached to the pad P20 and the pad P15 attached to the bump B8.

Each of the semiconductor chips 2000-1 and 2000-2 may be the HBM described with reference to FIG. 5. That is, each of the semiconductor chips 2000-1 and 2000-2 may be a die structure in which the buffer die 700 and the plurality of core dies 800, 900, 1000, and 1100 are vertically stacked.

The semiconductor chip 1300 may be an integrated circuit (IC) having hundreds to millions of semiconductor elements integrated therein. For example, the semiconductor chip 1300 may be an application processor (AP) such as a central processing unit (CPU), a graphics processing unit (GPU), a field programmable gate array (FPGA), a digital signal processor, a cryptographic processor, a microprocessor, and a microcontroller, but the present disclosure is not limited thereto. For example, the semiconductor chip 1300 may be a logic chip such as an analog-to-digital converter (ADC) or an application-specific integrated circuit (ASIC), or a memory chip such as a volatile memory (e.g., a dynamic random-access memory (DRAM)) or a nonvolatile memory (e.g., a read-only memory (ROM) or flash memory). Further, the semiconductor chip 1300 may be configured with a combination thereof.

The mold layer 400B may be disposed on the surface S4 corresponding to the upper surface of the interposer 200. The mold layer 400B may include a surface S11′ and a surface S12′ that are opposite to each other in the first direction DR1. The surface S11′ may be in contact with the surface S4 of the interposer 200. Although FIG. 6 illustrates that the surface S12′ of the mold layer 400B is located on the same plane as the upper surfaces of the semiconductor chips 1300, 2000-1, and 2000-2 and the upper surfaces of the semiconductor chips 1300, 2000-1, and 2000-2 are exposed by the mold layer 400B, the embodiments are not limited thereto. For example, in some embodiments, the surface S12′ corresponding to the upper surface of the mold layer 400B may be located at a high level in the first direction DR1 than the upper surfaces of the semiconductor chips 1300, 2000-1, and 2000-2, so that the mold layer 400B may cover, overlap, or be on the upper surfaces of the semiconductor chips 1300, 2000-1, and 2000-2.

The mold layer 400B may cover, overlap, or be on at least a part of the side surface of the semiconductor chip 1300, may cover, overlap, or be on at least a part of the side surface of the semiconductor chip 2000-1, and may cover, overlap, or be on at least a part of the side surface of the semiconductor chip 2000-2. The mold layer 400B may cover, overlap, or be on the surface that is not covered by or overlapped by the underfill film 500C in the surface S4 of the interposer 200 corresponding to the upper surface of the circuit layer 202. The mold layer 400B may include an insulating resin, e.g., prepreg, Ajinomoto build-up film (ABF), FR-4, bismaleimide triazine (BT), epoxy molding compound (EMC), or the like.

The underfill film 500C may be interposed between the interposer 200 and the semiconductor chip 1300, between the interposer 200 and the semiconductor chip 2000-1, and between the interposer 200 and the semiconductor chip 2000-2. The underfill film 500C may fill the space between the interposer 200 and the semiconductor chip 1300, the space between the interposer 200 and the semiconductor chip 2000-1, and the space between the interposer 200 and the semiconductor chip 2000-2. The underfill film 500C may cover, overlap, or be on the bump B8, and may cover, overlap, or be on at least some of the pads P15. The underfill film 500C may include an insulating polymer material, e.g., epoxy resin.

Referring to FIG. 7, a semiconductor package 3000A may include a plurality of stacked memory devices 3100a, 3100b, 3100c, and 3100d and a system-on-chip 3200. The stacked memory devices 3100a, 3100b, 3100c, and 3100d and the system-on-chip 3200 may be stacked on the interposer 3300, and the interposer 3300 may be stacked on a package substrate 3400. The semiconductor package 3000A may transmit and receive signals to and from other external packages or semiconductor devices through a solder ball 3001 attached to the bottom of the package substrate 3400. The package substrate 3400 may correspond to the substrate 100 of FIG. 6, the interposer 3300 may correspond to the interposer 200 of FIG. 6, and the solder ball 3001 may correspond to the connection terminal B1 of FIG. 6.

Each of the stacked memory devices 3100a, 3100b, 3100c, and 3100d may be implemented based on HBM standards. However, the embodiments are not limited thereto, and each of the stacked memory devices 3100a, 3100b, 3100c, and 3100d may be implemented based on Graphics DDR (GDDR), Hybrid Memory Cube (HMC), or Wide I/O standards. Each of the stacked memory devices 3100a, 3100b, 3100c, and 3100d may correspond to the stacked memory device 2000-1 or 2000-2 of FIG. 6.

The system-on-chip 3200 may include at least one processor, such as a CPU, an AP, a GPU, or an NPU, and a plurality of memory controllers for controlling the plurality of stacked memory devices 3100a, 3100b, 3100c, and 3100d. The system-on-chip 3200 may transmit and receive signals to and from a corresponding stacked memory device through a memory controller. The system-on-chip 3200 may correspond to the semiconductor chip 1300 of FIG. 6.

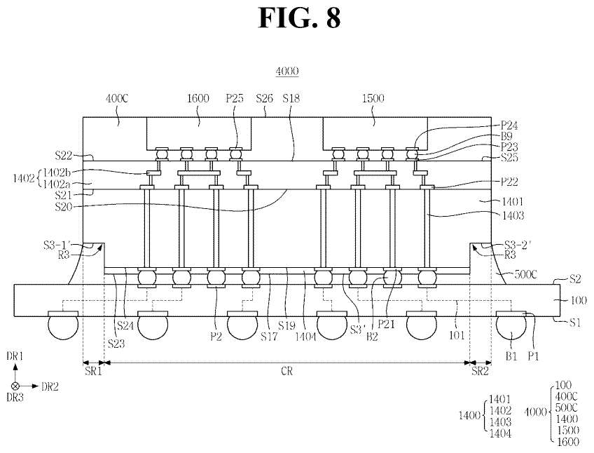

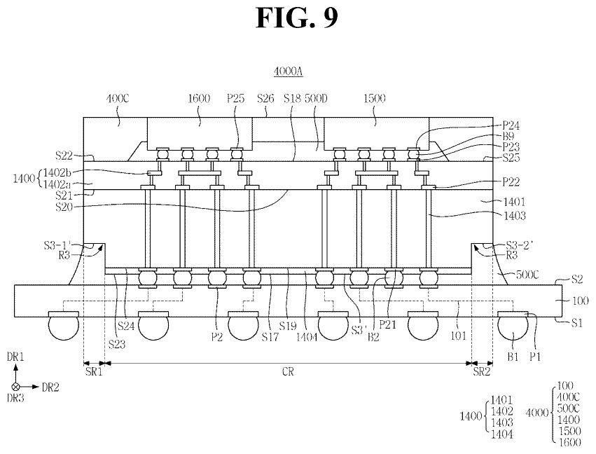

FIGS. 8 and 9 are diagrams illustrating semiconductor packages according to some embodiments.

Referring to FIG. 8, a semiconductor package 4000 may include the substrate 100, a semiconductor chip 1400, a semiconductor chip 1500, a semiconductor chip 1600, a mold layer 400C, and the underfill film 500C. In the following description, redundant description of the above embodiments will be omitted while focusing on differences.

The semiconductor chip 1400 may be disposed on the surface S2 of the substrate 100. The semiconductor chip 1400 may include a surface S17 and a surface S18 that are opposite to each other in the first direction DR1. The semiconductor chip 1400 may include a base substrate 1401, a circuit layer 1402, a through via 1403, and a passivation layer 1404.

The base substrate 1401 may be disposed on the substrate 100, and may include a surface S19 facing the substrate 100 and a surface S20 opposite to the surface S19 in the first direction DR1. The base substrate 1401 may be a semiconductor wafer. The base substrate 1401 may have a rectangular shape in which a side in the second direction DR2 is greater than a side in the third direction DR3. The base substrate 1401 may include a semiconductor element such as silicon and germanium, or a compound semiconductor such as silicon carbide (SiC), gallium arsenide (GaAs), indium arsenide (InAs), and/or indium phosphide (InP). The surface S19 or S20 of the base substrate 1401 may be covered with or overlapped by an insulating film formed of a silicon oxide film, a silicon nitride film, or a combination thereof.

The circuit layer 1402 may be disposed on the surface S20 of the base substrate 1401. The circuit layer 1402 may be in contact with the surface S20 of the base substrate 1401. However, the location of the circuit layer 1402 is not limited thereto, and the circuit layer 1402 may be disposed on the surface S19 of the base substrate 1401 depending on embodiments. The circuit layer 1402 may include a surface S21 and a surface S22 that are opposite to each other in the first direction DR1. The surface S21 corresponding to the lower surface of the circuit layer 1402 may be on the same plane as the surface S20 of the base substrate 1401. The surface S22 corresponding to the upper surface of the circuit layer 1402 may be on the same plane as a surface S25 corresponding to the lower surface of the mold layer 400C. The circuit layer 1402 may include an insulating member 1402a and a wiring structure 1402b.

The insulating member 1402a may be an insulating layer covering or overlapping the wiring structure 1402b. The insulating member 1402a may include silicon oxide or silicon nitride.

The wiring structure 1402b may be disposed in the insulating member 1402a. The wiring structure 1402b may include a plurality of wiring patterns spaced apart in the first direction DR1 and a plurality of vias connecting the plurality of wiring patterns.

Each of the plurality of wiring patterns may be a power wiring, a ground wiring, a signal wiring, or the like. The number of layers of the plurality of wiring patterns is not limited to the number shown in the drawing, and three to five pattern layers may be stacked, for example. The thickness of the plurality of wiring patterns may be within a range of about 1 μm to about 2 μm. The plurality of vias may connect the plurality of wiring patterns to each other or connect the plurality of wiring patterns to the pads P22 and P23.

The wiring structure 1402b may electrically and/or physically connect the through via 1403 to the semiconductor chips 1500 and 1600. The wiring structure 1402b may be electrically connected to the wiring structure 101 of the substrate 100 through the through via 1403. Accordingly, the wiring structure 1402b may electrically connect each of the semiconductor chips 1500 and 1600 to the wiring structure 101 of the substrate 100. The wiring structure 1402b may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). However, the material of the wiring structure 1402b is not limited to the above-mentioned materials.

The through via 1403 may be a through silicon via (TSV) that penetrates or extends into the base substrate 1401 in the first direction DR1. The through via 1403 may provide an electrical path that connects a pad P21 formed on the surface S19 of the base substrate 1401 to the pad P22 formed on the surface S20 of the base substrate 1401. The through via 1403 may electrically connect the wiring structure 101 of the substrate 100 to the wiring structure 1402b of the semiconductor chip 1400.

The through via 1403 may include a metal material, such as tungsten (W), titanium (Ti), aluminum (Al), or copper (Cu), and include a metal compound such as tungsten nitride (WN), titanium nitride (TiN), or tantalum nitride (TaN). The through via 1403 may be formed by a plating process, a PVD process, or a CVD process.

The passivation layer 1404 may be formed on the surface S19 of the base substrate 1401. The passivation layer 1404 may include a surface S23 and a surface S24 that are opposite to each other in the first direction DR1. The surface S23 may be disposed close to the substrate 100. The surface S23 corresponding to the lower surface of the passivation layer 1404 may be on the same plane as the surface S17 corresponding to the lower surface of the semiconductor chip 1400. The surface S24 corresponding to the upper surface of the passivation layer 1404 may be on the same plane as the surface S19 corresponding to the lower surface of the base substrate 1401.

The passivation layer 1404 may be a layer that covers, overlaps, or is on a part of the through via 1403 exposed by removing a part of the base substrate 1401 by a CMP process or the like. The passivation layer 1404 may be formed of an insulating layer such as a silicon oxide film, a silicon nitride film, a silicon oxynitride film, or the like. However, the material of the passivation layer 1404 is not limited to the above materials. For example, the passivation layer 1404 may be formed of a polymer such as polyimide (PI). Further, the passivation layer 1404 is not formed only on the surface S19 of the base substrate 1401, but may also be formed on the upper surface of the circuit layer 1402. Inside the passivation layer 1404, a pad P21 may be patterned in a region in contact with the lower surface of the through via 1403.

The pad P21 may be disposed on the surface S19 of the base substrate 1401. The pad P21 may be in contact with the passivation layer 1404 disposed on the surface S19 of the base substrate 1401. The pad P21 may be in physical contact with the bump B2. The pad P21 may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The pad P22 may be disposed on the surface S20 of the base substrate 1401. The pad P23 may be disposed in a region in contact with the upper surface of the circuit layer 1402. The pad P23 may be in physical contact with the bump B9. The pad P23 may include, a metal material, for example, an alloy containing two or more metals or at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The semiconductor chips 1500 and 1600 may be disposed horizontally on the semiconductor chip 1400. The semiconductor chips 1500 and 1600 may be disposed on the semiconductor chip 1400 to be spaced apart from each other. For example, the semiconductor chips 1500 and 1600 may be spaced apart from each other in the second direction DR2.

The lower surface of the semiconductor chip 1500 may be disposed close to the semiconductor chip 1400. The semiconductor chip 1500 may include a plurality of pads P24. The plurality of pads P24 may include a signal pad for connecting the semiconductor chip 1500 to the semiconductor chip 1400 and a ground pad and a power pad to be connected to the outside through a wiring. A bump B9 may be disposed between the semiconductor chip 1500 and the semiconductor chip 1400. The upper surface of the bump B9 may be in contact with the pad P24, and the lower surface of the bump B9 may be in contact with a pad P23.

The lower surface of the semiconductor chip 1600 may be disposed close to the semiconductor chip 1400. The semiconductor chip 1600 may include a plurality of pads P25. The plurality of pads P25 may include a signal pad for connecting the semiconductor chip 1600 to the semiconductor chip 1400 and a ground pad and a power pad to be connected to the outside through a wiring. The bump B9 may be disposed between the semiconductor chip 1600 and the semiconductor chip 1400. The upper surface of the bump B9 may be in contact with the pad P25, and the lower surface of the bump B9 may be in contact with the pad P23.

In the semiconductor package 4000, each of the semiconductor chips 1400, 1500, and 1600 may include, for example, a logic chip such as an application-specific IC (ASIC), a central processing unit (CPU), a graphics processing unit (GPU), a field programmable gate array (FPGA), a digital signal processor (DSP), a cryptographic processor, a microprocessor, a microcontroller, or an analog-to-digital converter. That is, the vertically stacked semiconductor chips 1400, 1500, and 1600 may all be implemented as logic chips.

Depending on embodiments, the semiconductor chip 1400 may include a logic chip such as an application-specific integrated circuit (ASIC), a central processing unit (CPU), a graphics processing unit (GPU), a field programmable gate array (FPGA), a digital signal processor (DSP), a cryptographic processor, a microprocessor, a microcontroller, or an analog-to-digital converter, and each of the semiconductor chips 1500 and 1600 may include a volatile memory device such as a DRAM or SRAM, a non-volatile memory device such as a PRAM, MRAM, RRAM or flash memory device, or the like. That is, among the vertically stacked semiconductor chips 1400, 1500, and 1600, the semiconductor chip 1400 which is a bottom die may be a logic chip, and the semiconductor chips 1500 and 1600 which are top dies may be memory chips.

Depending on embodiments, the semiconductor chip 1400 may include a logic chip such as an application-specific integrated circuit (ASIC), a central processing unit (CPU), a graphics processing unit (GPU), a field programmable gate array (FPGA), a digital signal processor (DSP), a cryptographic processor, a microprocessor, a microcontroller, or an analog-to-digital converter, and one of the semiconductor chips 1500 and 1600 stacked on the semiconductor chip 1400 may include a logic chip, and the other may include a volatile memory device or a non-volatile memory device. That is, among the vertically stacked semiconductor chips 1400, 1500, and 1600, the semiconductor chip 1400 which is a bottom die may be a logic chip, some of the semiconductor chips 1500 and 1600 which are top dies may be logic chips, and others may be memory chips.

The mold layer 400C may be disposed on the surface S18 of the semiconductor chip 1400. The mold layer 400C may include a surface S25 and a surface S26 that are opposite to each other in the first direction DR1. The surface S23 may be in contact with the surface S18 of the semiconductor chip 1400. Although FIG. 8 illustrates that the surface S26 of the mold layer 400C is located on the same plane as the upper surfaces of the semiconductor chips 1500 and 1600, and the upper surfaces of the semiconductor chips 1500 and 1600 are exposed by the mold layer 400C, the embodiment is not limited thereto. For example, in some embodiments, the surface S26 corresponding to the upper surface of the mold layer 400C may be located at a higher level in the first direction DR1 than the upper surfaces of the semiconductor chips 1500 and 1600, so that the mold layer 400C may cover, overlap, or be on the upper surfaces of the semiconductor chips 1500 and 1600.

The mold layer 400C may cover, overlap, or be on at least a part of each of the side surfaces of the semiconductor chips 1500 and 1600, and may cover, overlap, or be on the surface S18 of the semiconductor chip 1400. The mold layer 400C may cover, overlap, or be on at least a part of each of the lower surfaces of the semiconductor chips 1500 and 1600, and may cover, overlap, or be on the pad P23 and the bump B9. The mold layer 400C may include an insulating resin, e.g., prepreg, Ajinomoto build-up film (ABF), FR-4, bismaleimide triazine (BT), epoxy molding compound (EMC), or the like.

Similarly to the interposer 200 of FIG. 1, the semiconductor chip 1400 may include the scribe lane regions SR1 and SR2 and the chip region CR. The scribe lane regions SR1 and SR2 may define the chip region CR. That is, the chip region CR may be surrounded by the scribe lane regions SR1 and SR2. The semiconductor chips 1500 and 1600 mounted on the semiconductor chip 1400 may overlap the chip region CR in the first direction DR1. In addition, the semiconductor chips 1500 and 1600 may not overlap the scribe lane regions SR1 and SR2 in the first direction DR1.

The lower surface of the semiconductor chip 1400 may be divided into three surfaces S3′, S3-1′, and S3-2′. The sub-surface S3-1′ and the sub-surface S3-2′ may be disposed at both edge portions of the semiconductor chip 1400, and the sub-surface S3-1′ and the sub-surface S3-2′ may be spaced apart from each other in the second direction DR2. The sub-surface S3-1′ may correspond to the scribe lane region SR1, and the sub-surface S3-2′ may correspond to the scribe lane region SR2. The surface S3′ may be disposed between the sub-surface S3-1′ and the sub-surface S3-2′. The surface S3′ may correspond to the chip region CR. The surface S3′ may be on the same plane as the surface S23 corresponding to the lower surface of the passivation layer 1404.

The lower surface of the semiconductor chip 1400 may have a stepped portion in the first direction DR1 depending on whether it corresponds to the chip region CR or the scribe lane regions SR1 and SR2. For example, the surface S3′ disposed at the center of the lower surface of the semiconductor chip 1400 may further include a shape that protrudes more in the opposite direction of the first direction DR1 than the sub-surfaces S3-1′ and S3-2′ respectively disposed at both edge portions of the lower surface of the semiconductor chip 1400.

The lower surface of the semiconductor chip 1400 may include recesses R3. One recess R3 may be formed in each of the sub-surfaces S3-1′ and S3-2′ respectively disposed at both edge portions of the lower surface of the semiconductor chip 1400. Each of the recesses R3 may have a shape recessed inward from the surface S3′ disposed at the center of the lower surface of the semiconductor chip 1400. For example, the recesses R3 may be portions recessed in the first direction DR1 from the surface S3′ of the semiconductor chip 1400 corresponding to the chip region CR. The recesses R3 may be disposed at both edge portions of the semiconductor chip 1400. Any one recess R3 may correspond to the scribe lane region SR1, and another recess R3 may correspond to the scribe lane region SR2.

The description of the three surfaces S3′, S3-1′, and S3-2′ of the lower surface of the semiconductor chip 1400 and the recesses R3 formed in the lower surface of the semiconductor chip 1400 is the same as the description of the three surfaces S3, S3-1, and S3-2 of the lower surface of the interposer 200 and the recesses R formed in the lower surface of the interposer 200 which was made with reference to FIG. 1, so that the redundant description will be omitted below.

The recesses R3 formed to be recessed inward from the lower surface of the semiconductor chip 1400 may expose at least a partial surface of the base substrate 1401 of the semiconductor chip 1400. The circuit layer 1402 of the semiconductor chip 1400 and the mold layer 400C formed on the semiconductor chip 1400 may not be exposed by the recesses R3.

However, depending on embodiments, as shown in FIG. 2, the recesses R3 may be less recessed into the semiconductor chip 1400 than those shown in FIG. 8, so that a part of the passivation layer 1404 may be exposed, and the base substrate 1401, the circuit layer 1402, and the mold layer 400C may not be exposed. In some embodiments, as shown in FIG. 3, the recesses R3 may be more recessed into the semiconductor chip 1400 than those shown in FIG. 8, so that the circuit layer 1402 may be exposed. However, also in this case, the mold layer 400C may not be exposed.

The underfill film 500C may be interposed between the substrate 100 and the semiconductor chip 1400 to fill the space between the substrate 100 and the semiconductor chip 1400. The underfill film 500C may cover, overlap, or be on the bump B2, and may cover, overlap, or be on the lower surface of the passivation layer 1404 and the surface S2 of the substrate 100. Further, the underfill film 500C may fill the recesses R3. The underfill film 500C may include an insulating polymer material, e.g., epoxy resin. The description of the underfill film 500C is the same as the description of the underfill film 500 shown in FIG. 1, so that the redundant description will be omitted below.

Referring to FIG. 9, unlike the semiconductor package 4000 of FIG. 8, a semiconductor package 4000A may further include an underfill film 500D. The underfill film 500D may be interposed between the semiconductor chip 1400 and the semiconductor chip 1500, and between the semiconductor chip 1400 and the semiconductor chip 1600. The underfill film 500D may fill the space between the semiconductor chip 1400 and the semiconductor chip 1500, and the space between the semiconductor chip 1400 and the semiconductor chip 1600. The underfill film 500D may cover, overlap, or be on the bump B9, and may cover, overlap, or be on at least some of the pads P23. The underfill film 500D may include an insulating polymer material, e.g., epoxy resin. In this case, the mold layer 400C may cover, overlap, or be on at least a part of the underfill film 500D, and may cover, overlap, or be on a region of the surface S18 of the semiconductor chip 1400 that is not covered or overlapped by the underfill film 500D.

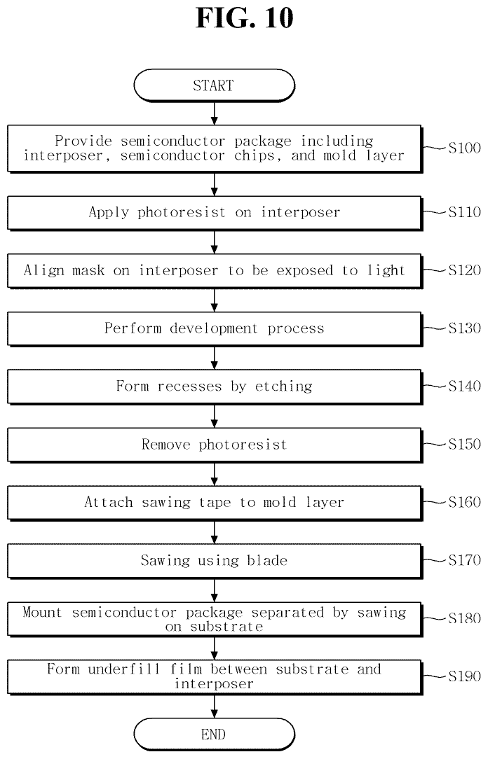

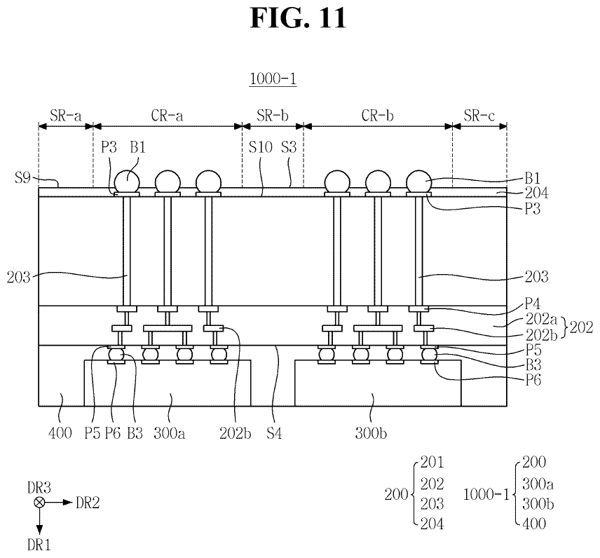

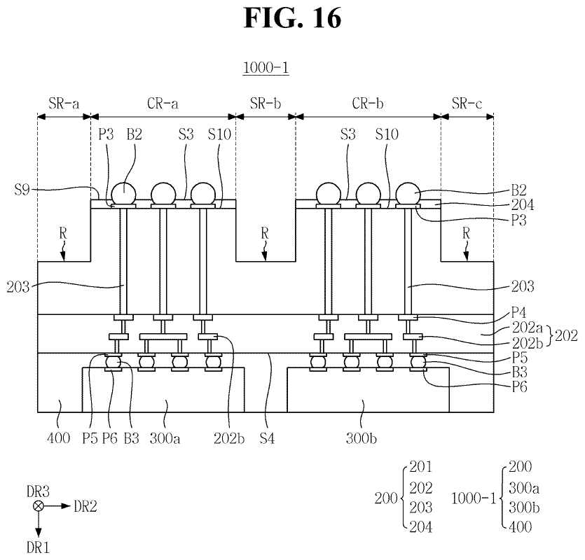

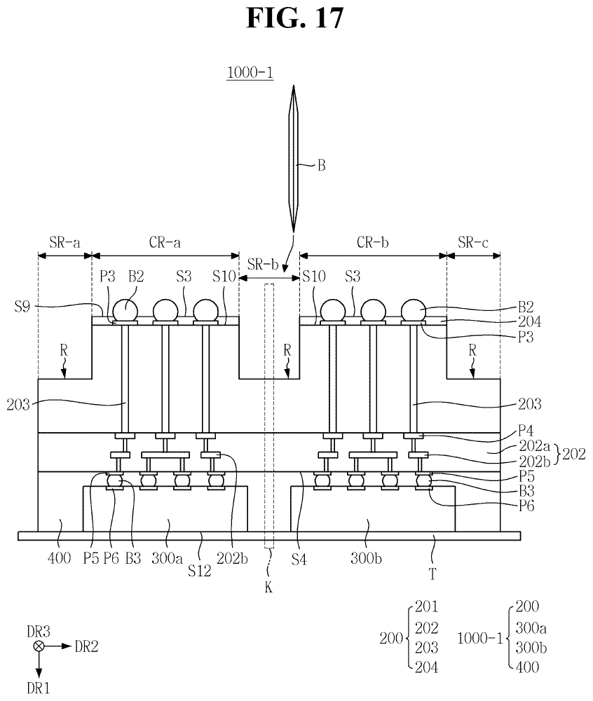

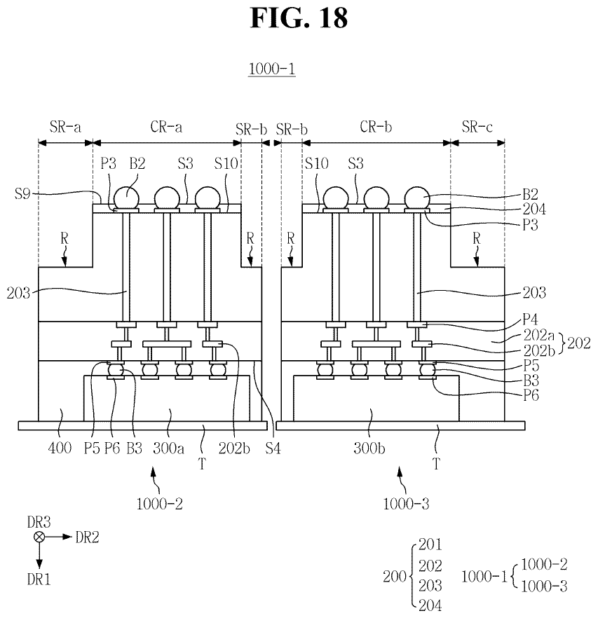

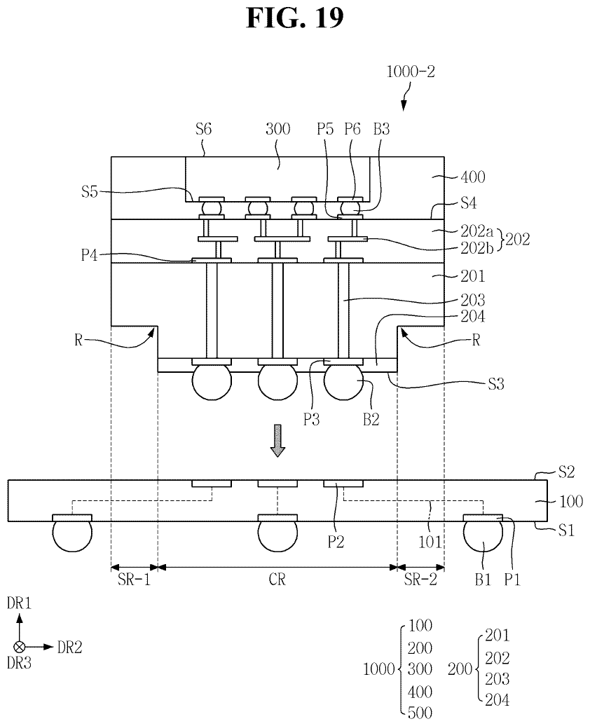

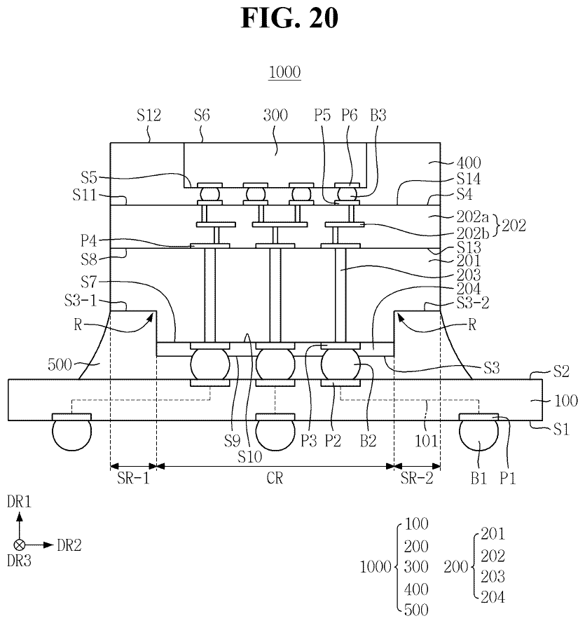

FIG. 10 is a flowchart illustrating a method for fabricating a semiconductor package according to some embodiments. FIGS. 11, 12, 13, 14, 15, 16, 17, 18, 19, and 20 are views illustrating the intermediate steps of a method for fabricating a semiconductor package according to some embodiments.

Hereinafter, a method for fabricating a semiconductor package according to some embodiments will be described with reference to FIGS. 10, 11, 12, 13, 14, 15, 16, 17, 18, 19, and 20.

First, referring to FIGS. 10 and 11, a semiconductor package 1000-1 including the interposer 200, semiconductor chips 300a and 300b, and the mold layer 400 may be provided (step S100). In the semiconductor package 1000-1, the semiconductor chips 300a and 300b may be stacked on the interposer 200, the mold layer 400 surrounding the surface S4 of the interposer 200 and the semiconductor chips 300a and 300b may be formed on the interposer 200, and the connection terminal B1 may be attached to the sub-surface S3 of the interposer 200. Further, the semiconductor chip 300a and the semiconductor chip 300b on the interposer 200 may be separated from each other by a sawing process to be performed later. The semiconductor chips 300a and 300b may correspond to the semiconductor chip 300 of FIG. 1.

The interposer 200 may include scribe lane regions SR-a, SR-b, and SR-c and chip regions CR-a and CR-b. The semiconductor chip 300a may overlap the chip region CR-a in the first direction DR1, and the semiconductor chip 300b may overlap the chip region CR-b in the first direction DR1. The scribe lane region SR-b may be a region that is disposed between the semiconductor chip 300a and the semiconductor chip 300b and cut by a blade in a sawing process to be performed later. Although FIG. 11 illustrates that only two semiconductor chips 300a and 300b are mounted on the interposer 200, another semiconductor chip may be mounted on the interposer 200 with the scribe lane region SR-a interposed therebetween in the opposite direction of the second direction DR2 from the semiconductor chip 300a. Further, another semiconductor chip may be mounted on the interposer 200 with the scribe lane region SR-c interposed therebetween in the second direction DR2 from the semiconductor chip 300b. Hereinafter, a case in which the semiconductor chip 300a and the semiconductor chip 300b are mounted on the interposer 200, and a blade cuts the scribe lane region SR-b between the semiconductor chip 300a and the semiconductor chip 300b will be described as an example. However, the following description may also be applied to a case in which a sawing process is performed by cutting portions between a plurality of different semiconductor chips mounted on the interposer 200 using a blade.

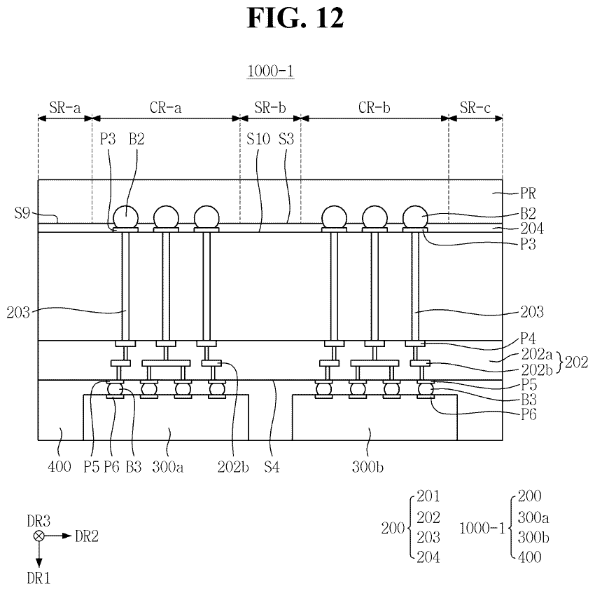

Next, referring to FIGS. 10 and 12, a photoresist PR may be applied on the surface S3 of the interposer 200 (step S110). The photoresist PR may be evenly applied on the surface S3 of the interposer 200 to cover, overlap, or be on the surface S9 of the passivation layer 204 and the connection terminal B1. Although a case in which the photoresist PR is a positive photoresist is described as an example, the photoresist PR may be a negative photoresist depending on embodiments.

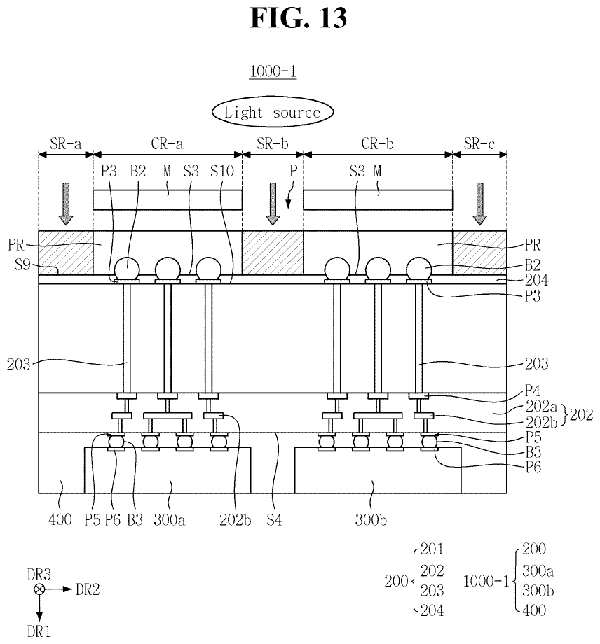

Next, referring to FIGS. 10 and 13, a mask M in which a pattern P is formed may be aligned on the interposer 200 in which the photoresist PR is formed on the passivation layer 204, and may be exposed to light (step S120). In this case, the mask M may be spaced apart from the photoresist PR by a predetermined interval in the opposite direction of the first direction DR1. The mask M may include the pattern P for forming the recesses R in the surface S3 of the interposer 200. For example, the mask M may include the pattern P that allows the scribe lane regions SR-a, SR2-b, and SR-c to be exposed to light from a light source, and prevents the chip regions CR-a and CR-b from being exposed to light from the light source. Accordingly, portions of the photoresist PR formed on the interposer 200 that correspond to the scribe lane regions SR-a, SR2-b, and SR-c react to light and, thus, the recesses R may be formed in the lower surface of the interposer 200 corresponding to the scribe lane regions SR-a, SR2-b, and SR-c when they are subjected to a development process and an etching process later. On the other hand, portions of the photoresist PR formed on the interposer 200 that correspond to the chip regions CR-a and CR-b do not react to light and, thus, the recesses R may not be formed in the lower surface of the interposer 200 corresponding to the chip regions CR-a and CR-b when they are subjected to the development process and the etching processes later.

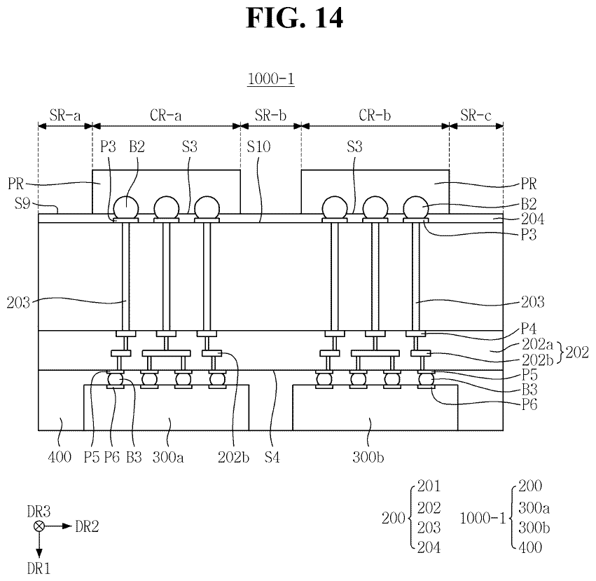

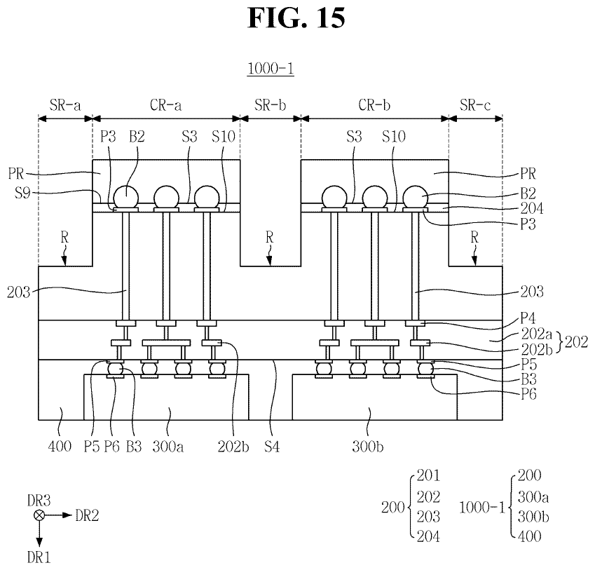

Next, referring to FIGS. 10 and 14, the mask M may be removed, and the photoresist PR may be developed (step S130). Next, referring to FIGS. 10 and 15, the recesses R may be formed by an etching process after the development process (step S140). Due to the etching process, in the scribe lane regions SR-a, SR2-b, and SR-c, the recesses R may include a shape recessed inward (i.e., in the first direction DR1) from the surface S3 that protrudes most in the opposite direction of the first direction DR1 in the lower surface of the interposer 200. In some embodiments, the etching process may be performed by a dry etching method using plasma.

Next, referring to FIGS. 10, 16, and 17, the photoresist PR may be finally removed from the interposer 200 (step S150), and a sawing tape T may be attached (step S160). In this case, the sawing tape T may be attached to the surface of the mold layer 400 that is opposite to the surface where the recesses R are formed, that is, the surface S12 of the mold layer 400. Next, referring to FIGS. 10, 17, and 18, the semiconductor package 1000-1 may be separated for each of semiconductor chips 300a and 300b by performing a sawing process using a blade B (step S170). By separating the semiconductor package 1000-1 for each of the semiconductor chips 300a and 300b, the semiconductor package 1000-1 may be separated into a semiconductor package 1000-2 including the semiconductor chip 300a and a semiconductor package 1000-3 including the semiconductor chip 300b. In this case, the blade B may be inserted to occupy an area corresponding to a kerf width K of the scribe lane region SR-b between the semiconductor chip 300a and the semiconductor chip 300b. The blade B may completely cut the base substrate 201, the circuit layer 202, the mold layer 400, and the sawing tape T in the first direction DR1 to completely separate the semiconductor chip 300a and the semiconductor chip 300b.

Next, referring to FIGS. 10, 19, and 20, the semiconductor package 1000-2 separated by the sawing process may be mounted on the substrate 100 (step S180) and then, the underfill film 500 may be formed between the substrate 100 and the interposer 200 to finally fabricate the semiconductor package 1000 (step S190).

FIGS. 21 and 22 are diagrams illustrating effects of a semiconductor package according to some embodiments.

First, referring to FIG. 21, FIG. 21 is a diagram illustrating cutting of layers L1, L2, and L3 using the blade B. In this case, the layers L1, L2, and L3 may be components to be cut by the blade B in the sawing process, and the passivation layer 204, the base substrate 201, the circuit layer 202, and the mold layer 400 constituting the interposer 200 of FIG. 1 may correspond to any one of the layers L1, L2, and L3. The layers L1, L2, and L3 to be cut by the blade B may overlap each other in the first direction DR1, and the layers L1, L2, and L3 may have different thermal expansion coefficients. If impact is applied by cutting the layers L1, L2, and L3 using the blade B in a sawing process in a state where the layers L1, L2, and L3 are under tension, the multiple layers L1, L2, and L3 may be separated at once and an internal stress may be released all at once. Accordingly, cracks may occur in a weak portion in the semiconductor chip 300 (shown in FIG. 1), for example, the edge portion of the semiconductor chip 300.

Referring to FIG. 22, before the layers L1, L2, and L3 are cut by the blade B, that is, before the sawing process is performed, the recesses R including a shape recessed in the first direction DR1 may be formed in at least some of the layers L1, L2, and L3. For example, as shown in FIG. 22, when the layer L1 is partially etched in the first direction DR1 to form the recesses R, the layer L1 may be separated into a plurality of regions in the second direction DR2 with the recesses R interposed therebetween. Similarly, when the layer L2 is partially etched in the first direction DR1 to form the recesses R, the layer L2 may be separated into a plurality of regions in the second direction DR2 with the recesses R interposed therebetween. When the layer L1 and the layer L2 are separated into a plurality of regions, the internal stress of each of the layers L1, L2, and L3 may be reduced. Accordingly, when the blade B is inserted into the recesses R formed in the layer L1 and the layer L2 to cut the entire layers L1, L2, and L3 in the first direction DR1, a phenomenon that an internal stress is released at once and cracks occur in the semiconductor chip 300 (shown in FIG. 1) may be reduced.

While the present disclosure has been particularly illustrated and described with reference to example embodiments thereof, it will be understood by those of ordinary skill in the art that various changes in form and detail may be made therein without departing from the spirit and scope of the present disclosure as defined by the following claims. The example embodiments should be considered in a descriptive sense only and not for purposes of limitation.

What is claimed is:

1. A semiconductor package comprising:
a substrate comprising a first wiring structure, and comprising a first surface and a second surface opposite to each other in a first direction;
an interposer on the second surface of the substrate, comprising a scribe lane region, and a chip region defined by the scribe lane region, and comprising a third surface and a fourth surface opposite to each other in the first direction;
a first semiconductor chip on the fourth surface of the interposer; and
a mold layer on the fourth surface of the interposer, and on a side surface of the first semiconductor chip,
wherein the third surface of the interposer is closer to the substrate than the fourth surface of the interposer,
wherein the third surface of the interposer comprises a first sub-surface corresponding to the scribe lane region and a second sub-surface corresponding to the chip region, and
wherein a distance in the first direction from the second surface of the substrate to the second sub-surface is less than a distance in the first direction from the second surface of the substrate to the first sub-surface.

2. The semiconductor package of claim 1, further comprising:
an underfill film in a space between the substrate and the interposer,
wherein a thickness of the underfill film on the chip region in the first direction is less than a thickness of the underfill film on the scribe lane region in the first direction.

3. The semiconductor package of claim 2, further comprising:
a first bump between the substrate and the interposer,
wherein the underfill film is on the first bump.

4. The semiconductor package of claim 1, wherein the interposer further comprises:
a base substrate comprising a fifth surface facing the substrate and a sixth surface opposite to the fifth surface in the first direction;
a circuit layer on the base substrate, and comprising a first insulating member and a second wiring structure in the first insulating member; and
a through via that extends into the base substrate in the first direction and electrically connects the first wiring structure to the second wiring structure,
wherein the mold layer is on the sixth surface of the base substrate.

5. The semiconductor package of claim 4, wherein the interposer further comprises a passivation layer comprising a seventh surface facing the substrate and an eighth surface opposite to the seventh surface in the first direction,
wherein the passivation layer is on the fifth surface of the base substrate, and
wherein the circuit layer comprises a ninth surface facing the substrate and a tenth surface opposite to the ninth surface in the first direction.

6. The semiconductor package of claim 5, wherein a length in the first direction from the tenth surface of the circuit layer to the first sub-surface is less than or equal to ½ of a length in the first direction from the tenth surface of the circuit layer to the seventh surface of the passivation layer.

7. The semiconductor package of claim 1, further comprising:
a first bump between the interposer and the first semiconductor chip,
wherein the mold layer is on the fourth surface of the interposer and the first bump.

8. The semiconductor package of claim 1, further comprising:
a second semiconductor chip on the fourth surface of the interposer,
wherein a first one of the first and second semiconductor chips comprises a high bandwidth memory (HBM), and a second one of the first and second semiconductor chips comprises a logic chip.

9. A semiconductor package comprising:
a substrate comprising a wiring structure, and comprising a first surface and a second surface opposite to each other in a first direction;
a first semiconductor chip on the second surface of the substrate, and comprising a third surface and a fourth surface opposite to each other in the first direction, the first semiconductor chip comprising a first region and a second region spaced apart from each other at edge portions of the first semiconductor chip, and a third region between the first region and the second region;
a second semiconductor chip on the fourth surface of the first semiconductor chip; and
a mold layer on the fourth surface of the first semiconductor chip, on at least a part of a side surface of the second semiconductor chip, and comprising a fifth surface and a sixth surface opposite to each other in the first direction,
wherein the third surface of the first semiconductor chip is closer to the substrate than the fourth surface of the first semiconductor chip,
wherein a distance in the first direction from the fourth surface of the first semiconductor chip to the fifth surface of the mold layer is less than a distance from the fourth surface of the first semiconductor chip to the sixth surface of the mold layer in the first direction,
wherein the third surface comprises a first sub-surface corresponding to the first region and a second sub-surface corresponding to the third region, and
wherein a distance in the first direction from the sixth surface of the mold layer to the first sub-surface is less than a distance in the first direction from the sixth surface of the mold layer to the second sub-surface.

10. The semiconductor package of claim 9, wherein a distance in the first direction from first surface of the substrate to the fourth surface of the first semiconductor chip is greater than or equal to ½ of a distance in the first direction from the third surface of the first semiconductor chip to the fourth surface of the first semiconductor chip.

11. The semiconductor package of claim 9, wherein the first semiconductor chip comprises a logic chip, and the second semiconductor chip comprises a memory chip.

12. The semiconductor package of claim 9, wherein the first semiconductor chip is a first logic chip, and the second semiconductor chip is a second logic chip.

13. The semiconductor package of claim 9, further comprising:
an interposer;
an underfill film between the substrate and the interposer,
wherein the third surface of the first semiconductor chip further comprises a third sub-surface corresponding to the second region,
wherein a thickness of the underfill film on the second sub-surface in the first direction is less than a thickness of the underfill film on the first sub-surface in the first direction, and
wherein a thickness of the underfill film on the second sub-surface in the first direction is less than a thickness of the underfill film on the third sub-surface in the first direction.

14. The semiconductor package of claim 9, wherein the third surface of the first semiconductor chip further comprises:
a third sub-surface corresponding to the second region, and
wherein a length in the first direction from the sixth surface of the mold layer to the third sub-surface is less than a length in the first direction from the sixth surface of the mold layer to the second sub-surface.

15. The semiconductor package of claim 9, further comprising:
an underfill film in a space between the first semiconductor chip and the second semiconductor chip; and
a bump between the first semiconductor chip and the second semiconductor chip,
wherein the underfill film is on at least a part of the fourth surface of the first semiconductor chip and the bump, and
wherein the mold layer is on a region of the fourth surface of the first semiconductor chip that is not overlapped by the underfill film.

16. A semiconductor package comprising:
a substrate comprising a wiring structure, and comprising a first surface and a second surface opposite to each other in a first direction;
a buffer die on the second surface of the substrate, comprising a scribe lane region, and a chip region defined by the scribe lane region, and comprising a third surface and a fourth surface opposite to each other in the first direction;
a plurality of core dies stacked on a first region among regions of the fourth surface; and
a mold layer on a second region extending around the first region among the regions of the fourth surface in plan view and on at least a part of side surfaces of the plurality of core dies,
wherein the third surface of the buffer die is closer to the substrate than the fourth surface of the buffer die,
wherein the buffer die comprises a recess that is recessed inward from the third surface of the buffer die in the first direction, and
wherein the recess is in a region corresponding to the scribe lane region of the third surface of the buffer die.

17. The semiconductor package of claim 16, wherein the third surface of the buffer die comprises a first sub-surface having the recess therein and a second sub-surface distinct from the first sub-surface,
wherein the semiconductor package further comprises:
an underfill film between the substrate and the buffer die,
wherein the underfill film comprises a first sub-film in a space between the second surface of the substrate and the first sub-surface, and a second sub-film in a space between the second surface of the substrate and the second sub-surface, and
wherein a distance in the first direction from the second surface of the substrate to the first sub-surface is greater than a distance in the first direction from the second surface of the substrate to the second sub-surface.

18. The semiconductor package of claim 17, wherein a thickness of the second sub-film in the first direction is less than a thickness of the first sub-film in the first direction.

19. The semiconductor package of claim 17, wherein the second sub-surface is in the chip region,
wherein the recess is provided as a plurality of recesses, and
wherein the plurality of recesses are at edge portions of the third surface of the buffer die to be spaced apart from each other in a second direction intersecting with the first direction.

20. The semiconductor package of claim 17, wherein a length in the first direction from the fourth surface of the buffer die to the first sub-surface is greater than or equal to ½ of a length of the buffer die in the first direction.
